(19) United States
(12) Patent Application Publication
(10) Pub. No.: US 2011/0188532 A1
(43) Pub. Date: Aug. 4, 2011

(54) Semiconductor Laser Apparatus

(75) Inventors: Masayuki HATA, Takatsuki-shi (JP); Yasuhiko NOMURA, Osaka-shi (JP); Yasuyuki BESSHO, Uji-shi (JP)

(73) Assignee: SANYO ELECTRIC CO., LTD., Moriguchi-shi (JP)

(21) Appl. No.: 13/020,080

(22) Filed: Feb. 3, 2011

(30) Foreign Application Priority Data
Feb. 4, 2010 (JP) 2010-023313
Feb. 25, 2010 (JP) 2010-040128

(51) Int. Cl. H01S 5/40; H01S 5/323

(52) U.S. Cl. 372/50.12

(57) ABSTRACT

This semiconductor laser apparatus includes a first semiconductor laser device having a first surface and a second surface, an integrated laser device formed by a second semiconductor laser device and a third semiconductor laser device having a third surface and a fourth surface, and a support substrate. The third surface is bonded onto a first region of the support substrate, a first section of the first surface overlaps with at least part of the fourth surface, and a second section of the first surface is bonded to a second region of the support substrate.

### CROSS-REFERENCE TO RELATED APPLICATION

The priority application numbers JP2010-23313, Method of Manufacturing Semiconductor Laser Apparatus and Semiconductor Laser Apparatus, Feb. 4, 2010, Masayuki Hata et al., and JP2010-40128, Method of Manufacturing Semiconductor Laser. Apparatus and Semiconductor Laser Apparatus, Feb. 25, 2010, Masayuki Hata et al., upon which this patent application is based are hereby incorporated by reference.

### BACKGROUND OF THE INVENTION

1. Field of the Invention

The present invention relates to a semiconductor laser apparatus, and more particularly, it relates to a semiconductor laser apparatus having a plurality of semiconductor laser devices bonded to each other.

2. Description of the Background Art

An infrared semiconductor laser device having a wavelength of about 180 nm has been employed as a light source for a CE) (compact: disc)/CD-R (compact disc-recordable) drive in general. A red semiconductor laser device having a wavelength of about 650 nm has been employed as a light source for a DVD (digital versatile disc) drive.

On the other hand, a DVD allowing writing/reading by employing blue-violet light has recently been developed. For writing/reading of such a DVD, a blue DVD drive employing a blue-violet semiconductor laser device having a wavelength of about 405 nm has also simultaneously been developed. This DVD drive requires compatibility for conventional CD/CD-R and DVD.

In this case, the compatibility for the conventional CD, DVD and DVD allowing writing/reading is attained by a method of providing a plurality of optical pickups individually emitting infrared light, red light and blue-violet light in a DVD drive or a method of individually providing infrared, red and blue-violet semiconductor laser devices in one optical pickup. However, these methods cause increase of the number of components, and hence downsizing, simplified configuration or price-reduction of the pickup is disadvantageously difficult.

In order to suppress the increase of the number of components, a two-wavelength semiconductor laser device having an infrared laser and a red laser integrated in one chip has been out into practice in general. On the other hand, the blue-violet laser is not formed on a GaAs substrate, and hence it is very difficult to integrate the blue-violet semiconductor laser device together with the infrared and red semiconductor laser devices in one chip.

A semiconductor laser apparatus having a long-wavelength (wavelength of 600 to 700 nm band) laser device such as the red or infrared semiconductor laser device bonded to a short-wavelength (wavelength of 400 nm band) laser device such as the blue-violet semiconductor laser device is proposed in general, as disclosed in Japanese Patent Laying-Open Nos. 2004-207480 and 2005-317919, for example.

The aforementioned Japanese Patent Laying-Open No. 2004-207480 discloses a semiconductor laser device having a second light emitting element made of an AlGaAs-based semiconductor or an AlGaInP-based semiconductor bonded onto an upper surface of a first light emitting element made of a GaN-based (nitride-based) semiconductor through an adhesive metal layer. In this semiconductor laser apparatus described in Japanese Patent Laying-Open No. 2004-207480, respective surfaces of light emitting element layers at opposite sides of the light emitting elements to substrates are bonded to be opposed to each other, whereby a laser emitting portion of the second light emitting element is arranged along a thickness direction of the element at a prescribed distance from a laser emitting portion of the first light emitting element.

The aforementioned Japanese Patent Laying-Open No. 2005-317919 discloses a semiconductor laser apparatus having a red semiconductor laser device and an infrared semiconductor laser device bonded onto a surface of a blue-violet semiconductor laser device. In this semiconductor laser apparatus described in Japanese Patent, Laying-Open No. 2005-317919, the red and infrared semiconductor laser devices are bonded onto respective planar portions on both sides off a ridge portion formed on a substantially central portion of the blue-violet semiconductor laser device in a width direction. Respective surfaces of laser device layers at opposite sides of the laser devices to substrates are bonded to be opposed to each other, whereby a laser emitting portion of each of the red and infrared semiconductor laser devices is arranged in a thickness direction off the laser device at a prescribed distance from a laser emitting portion of the blue-violet semiconductor laser device.

However, in the semiconductor laser device disclosed in Japanese Patent Laying-Open No. 2004-207480, the respective surfaces of the light emitting element layers at the opposite sides of the light emitting elements to the substrates are bonded to be opposed to each other, and hence a size (thickness) of the semiconductor laser device is disadvantageously increased due to addition of a thickness of the second light emitting element to a thickness of the first light emitting element. The second light emitting element is bonded to the first light emitting element, and hence it is necessary to narrow a width of the second light emitting element bonded to the first light emitting element similarly when a width of the first light emitting element is narrowed, for example. Thus, the width of each of the light emitting elements narrows, whereby it is disadvantageously difficult to bond a metal wire or the like to each of the light emitting elements.

Also in the semiconductor laser apparatus disclosed in Japanese Patent Laying-Open No. 2005-317919, the respective surfaces of the laser device layers at the opposite sides of the laser devices to the substrates are bonded to be opposed to each other, and hence a size (thickness) of the semiconductor laser apparatus is disadvantageously increased due to addition of a thickness of the red (or infrared) semiconductor laser device to a thickness of the blue-violet semiconductor laser device. The red (or infrared) semiconductor laser device is bonded to the blue-violet semiconductor laser device, and hence it is necessary to narrow a width of the red (or infrared) semiconductor laser device similarly when a width of the blue-violet semiconductor laser device is narrowed, for example. Thus, the width of each of the laser devices narrows, whereby it is disadvantageously difficult to bond a metal wire or the like to each of the laser devices.

### SUMMARY OF THE INVENTION

A semiconductor laser apparatus according to a first aspect of the present invention comprises a first semiconductor laser device including a first surface and a second surface opposite to the first surface, an integrated laser device formed by a second semiconductor laser device and a third semiconductor laser device, and a support substrate, wherein the second semiconductor laser device includes a third surface and a fourth surface opposite to the third surface, one surface of the support substrate has a first region and a second region other than the first region, the first surface has a first section and a second section other than the first section, the third surface is bonded onto the first region, the first section overlaps with at least part of the fourth surface, and the second section is bonded to the second region.

As hereinabove described, the semiconductor laser apparatus according to the first aspect of the present invention comprises the first semiconductor laser device, the integrated laser device and the support substrate, and in the first semiconductor laser device, the first section overlaps with at least part of the fourth surface of the second semiconductor laser device while the second section is bonded to the second region of the support substrate. Thus, the first semiconductor laser device and the integrated laser device can be aligned in a lateral direction on the same one surface of the support substrate, and hence sizes (thicknesses) of the laser devices can be inhibited from increase, dissimilarly to a case where a semiconductor layer apparatus is formed by stacking the first semiconductor laser device and the integrated laser device in a thickness direction of the device and bonding the same to each other. Further, when the first semiconductor laser device and the integrated laser device are aligned in the lateral direction on the same one surface of the support substrate, the first section of the first semiconductor laser device overlaps with the fourth surface of the integrated laser device. Thus, the first semiconductor laser device is not formed such that a width thereof is excessively narrow, and hence an appropriate-sized wire-bonding region for bonding a metal wire can be secured. Consequently, the metal wire can be easily bonded to the first semiconductor laser device.

In the semiconductor laser apparatus according to the first aspect, the first semiconductor laser device preferably further includes a step portion formed on the first surface, a bottom portion of the step portion is preferably the first section, and a top portion of the step portion is preferably the second section. According to this structure, the second section of the first semiconductor laser device can be easily bonded onto the second region by effectively employing the step portion (stepped shape) formed on the first surface in a state where the first section of the first semiconductor laser device overlaps with the fourth surface of the integrated laser device.

In this case, a thickness of the integrated laser device is preferably not more than a height from the bottom portion to the top portion. According to this structure, the integrated laser device can be easily arranged between the one surface of the support substrate and the bottom portion of the step portion of the first semiconductor laser device.

In the semiconductor laser apparatus according to the first aspect, the first semiconductor laser device preferably has a first waveguide extending in a first direction, the first direction is in a plane of the support substrate, a second direction is preferably perpendicular to the first direction, the second direction is in the plane, the first waveguide is preferably formed at a position opposed to the second region, and the position preferably deviates in the second direction to the integrated laser device from a center of the second section in the second direction. According to this structure, a light-emitting point of the first semiconductor laser device can be rendered close to a central portion of the semiconductor laser apparatus in a width direction (the second direction). Thus, a plurality of laser beams emitted from the semiconductor laser apparatus can be rendered close to an optical axis of an optical system, and hence the semiconductor laser apparatus and the optical system can be easily adjusted.

In the semiconductor laser apparatus according to the first aspect, the first section is preferably bonded onto the fourth surface. According to this structure, in the first semiconductor laser device, the first surface is bonded onto not only the second region of the support substrate but also the fourth surface of the integrated laser device (second semiconductor laser device), and hence the number of bonded portions is increased, whereby the first semiconductor laser device can be reliably fixed onto the support substrate.

In the semiconductor laser apparatus according to the first aspect, the first semiconductor laser device preferably has a first active layer on a side closer to the first surface of the second section, and the second semiconductor laser device and the third semiconductor laser device preferably have a second active layer and a third active layer on a side closer to the third surface, respectively. According to this structure, a height from a lower surface of the support substrate to the first active layer of the first semiconductor laser device and a height from the lower surface of the support substrate to the second and third active layers of the integrated laser device can approximate each other. Further, heat of these semiconductor laser devices can be efficiently radiated through the support substrate. Consequently, the temperature characteristics and reliability of these semiconductor laser devices can be improved.

In the semiconductor laser apparatus according to the first aspect, the first semiconductor laser device preferably has a first waveguide extending in a first direction, the first direction is in a plane of the support substrate, a second direction is preferably perpendicular to the first direction, the second direction is in the plane, the second semiconductor laser device preferably has a second waveguide extending in the first direction, and the second waveguide is preferably arranged at a position deviating in the second direction to the second section from a center of the second semiconductor laser device in the second direction. According to this structure, a light-emitting point of the second semiconductor laser device can be rendered close to the central portion of the semiconductor laser apparatus in the width direction. Thus, the plurality of laser beams emitted from the semiconductor laser apparatus can be rendered close to the optical axis of the optical system, and hence the semiconductor laser apparatus and the optical system can be easily adjusted.

A semiconductor laser apparatus according to a second aspect of the present invention comprises a first semiconductor laser device including a first surface and a second surface opposite to the first surface, a second semiconductor laser device including a third surface and a fourth surface opposite to the third surface, a third semiconductor laser device including a fifth surface and a sixth surface opposite to the fifth surface, and a support substrate, wherein one surface of the support substrate has a first region, a third region and a second region other than the first and the third regions, the second region is held between the first region and the third region, the first surface has a first section, a third section and a second section other than the first and the third sections, the second section is held between the first section and the third section, the third surface is bonded onto the first region, the fifth surface is bonded onto the third region, the first section and the third section overlap with the fourth surface and the sixth surface, respectively, and the second section is bonded to the second region.

As hereinabove described, the semiconductor laser apparatus according to the second aspect of the present invention comprises the first semiconductor laser device, the second semiconductor laser device, the third semiconductor laser device and the support substrate, and in the first semiconductor laser device, the first section and the third section overlap with the fourth surface of the second semiconductor laser device and the sixth surface of the third semiconductor laser device, respectively while the second section is bonded onto the second region of the support substrate. Thus, the first semiconductor laser device and the second and third semiconductor laser devices can be aligned in a lateral direction on the same one surface of the support substrate, and hence sizes (thicknesses) of the laser devices can be inhibited from increase, dissimilarly to a case where a semiconductor layer apparatus is formed by stacking the first semiconductor laser device and the second or third semiconductor laser device in a thickness direction of the device and bonding the same to each other. Further, when the first semiconductor laser device and the second and third semiconductor laser devices are aligned in the lateral direction on the same one surface of the support substrate, the first section of the first semiconductor laser device overlaps with the fourth surface of the second semiconductor laser device and the sixth surface of the third semiconductor laser device. Thus, the first semiconductor laser device is not formed such that a width thereof is excessively narrow, and hence an appropriate-sized wire-bonding region for bonding a metal wire can be secured. Consequently, the metal wire can be easily bonded to the first semiconductor laser device.

In the semiconductor laser apparatus according to the first aspect, the second semiconductor laser device and the third semiconductor laser device are preferably made of a group III-V semiconductor including the greatest amount of phosphorus or arsenic as a group V element. In a case where the second semiconductor laser device and the third semiconductor laser device are made of a group semiconductor including the greatest amount of phosphorus or arsenic as a group V element, the second semiconductor laser device and the third semiconductor laser device are formed employing a growth substrate having low the thermal conductivity made of a GaAs substrate or the like, for example, thereafter the second semiconductor laser device and the third semiconductor laser device are bonded onto the first region of the support substrate while a surface of a laser device layer opposite to the growth substrate serves as a bonded surface, and thereafter a step of removing the growth substrate is applied. Thus, heat generated by the second semiconductor laser device and the third semiconductor laser device can be easily radiated to an external portion through the support substrate by employing the support substrate having higher thermal conductivity than the growth substrate.

A semiconductor laser apparatus according to a third aspect of the present invention comprises a first semiconductor laser device including a first surface and a second surface opposite to the first surface, a second semiconductor laser device including a third surface and a fourth surface opposite to the third surface, and an insulating support substrate, wherein the first semiconductor laser device is so arranged on the second semiconductor laser device that part of the first surface or the second surface overlaps with the fourth surface, a first electrode is formed on the first surface, a second electrode is formed on the third surface, the support substrate includes an upper surface and a lower surface, the second semiconductor laser device is bonded onto the upper surface, the lower, surface is an opposite surface to the upper surface, the support substrate includes a via having a conductive member, the via penetrates through the support substrate from the upper surface to the lower surface, and at least either the first electrode or the second electrode is bonded onto the upper surface and connected to the conductive member.

In the semiconductor laser apparatus according to the third aspect of the present invention, as hereinabove described, because the first semiconductor laser device is so arranged with respect to the second semiconductor laser device that part of the first surface or the second surface overlaps with the fourth surface, a plurality of the laser devices can be arranged in a state where a plane area of the support substrate is reduced. Hence a planar size of the semiconductor laser apparatus can be inhibited from increase even when the plurality of the laser devices are arranged on the support substrate.

According to the third aspect, the insulating support substrate includes the via having the conductive member, the via penetrates through the support substrate from the upper surface to the lower surface, and at least either the first electrode or the second electrode is bonded onto the upper surface and connected to the conductive member. Thus, when the second semiconductor laser device is electrically connected to an external portion, wire bonding can be performed by providing an extraction electrode on the lower surface. Therefore, a position where the wire bonding is performed is distanced downwardly from the upper surface of the support substrate onto which the laser devises are bonded, and hence damage of the laser devices in the wire bonding can be suppressed. Further, it is not necessary to perform wire bonding on the upper surface side of the support substrate to which the laser devices are bonded, and hence widths of the individual laser devices can be narrowed.

The semiconductor laser apparatus according to the third aspect preferably further comprises a submount, wherein a top surface of the submount is bonded onto the lower surface, an extraction elect is formed on the top surface, and the extraction electrode is connected to the conductive member. According to this structure, wire bonding can be easily performed on the extraction electrode formed on the top surface of the submount.

In the semiconductor laser apparatus according to the third aspect, the via preferably includes a first via and a second via, the first via is preferably connected to at least one of either the first semiconductor laser device or the second semiconductor laser device, the second via is preferably connected to at least the other of either the first semiconductor laser device or the second semiconductor laser device, the first semiconductor laser device preferably has a first waveguide extending in a first direction, the first direction is in a plane of the support substrate, the support substrate preferably has a first facet in the first direction, and a first distance between the first facet and a center position of the first via and a second distance between the first facet of the support substrate and a center position of the second via are different from each other. According to this structure, the first via and the second via can be arranged deviating to each other along a cavity direction of the laser device, and hence a plurality of the vias can be efficiently provided in the support substrate while increasing respective diameters of the vias even when the support substrate having a small width is employed.

In the semiconductor laser apparatus according to the first aspect, the first semiconductor laser device is preferably made of a group III-V semiconductor including the greatest amount of nitrogen as a group V element. Thus, a metal wire can be easily wire-bonded to the first semiconductor laser device, and hence the yield can be improved even when the first semiconductor laser device formed by a nitride-based semiconductor laser device is formed employing an expensive nitride-based semiconductor substrate.

In the semiconductor laser apparatus, according to the first aspect, the support substrate preferably has an insulating property or the one surface is preferably covered with an insulating film, the one surface preferably has an area other than the first and second regions, the first semiconductor laser device and the integrated semiconductor laser device are preferably not bonded onto this area, and an extraction electrode extending from the first region or the second region is preferably formed on this area. According to this structure, power can be easily supplied to the integrated laser device (second semiconductor laser device) by employing the extraction electrode extending from the first region arranged with the integrated laser device or the second region arranged with the first semiconductor laser device to the area onto which the semiconductor laser devices are not bonded even when the support substrate and the integrated laser device are electrically insulated from each other.

In the semiconductor laser apparatus according the first aspect, the first semiconductor laser device preferably has a first waveguide extending in a first direction, the first direction is in a plane of the support substrate, a second direction is preferably perpendicular to the first direction, the second direction is in the plane, and a width of the first semiconductor laser device in the second direction is preferably smaller than a width of the integrated laser device in the second direction. According to this structure, a width of the semiconductor laser apparatus can be easily suppressed from increase even when the first semiconductor laser device and the integrated laser device are aligned in a lateral direction. Further, the yield of the first semiconductor laser devices per wafer can be increased in a manufacturing process.

In the semiconductor laser apparatus according to the first aspect, the first semiconductor laser device preferably has a first waveguide extending in a first direction, the first direction is in a plane of the support substrate, and a length of the second semiconductor laser device in the first direction is preferably larger than a length of the first semiconductor laser device in the first direction. According to this structure, a cavity length of the first semiconductor laser device can be short, and hence the yield of the first semiconductor laser devices per wafer can be increased in the manufacturing process. Consequently, the manufacturing cost for the first semiconductor laser device can be reduced.

In the semiconductor laser apparatus according to the first aspect, the first semiconductor laser device preferably has a first waveguide extending in a first direction, the first direction is in a plane of the support substrate, a second direction is preferably perpendicular to the first direction, the second direction is in the plane, the first semiconductor laser device preferably has a support portion on the second section, and the support portion is preferably arranged at a position further away from the integrated laser device than the first waveguide. According to this structure, the first semiconductor laser device can be stably bonded to the one surface (second region) of the support substrate through a ridge (jut portion) and the support portion without inclination, dissimilarly to a case where the first semiconductor laser device has only the ridge for forming the first waveguide. Further, the first waveguide can be easily so arranged as to be close to the integrated laser device without a support portion.

In the structure in which the first section according to the first aspect is bonded onto the fourth surface, the second surface is preferably connected with a wire, and the wire and the integrated laser device are preferably electrically connected with each other. According to this structure, power can be supplied to not only the first semiconductor laser device but also the integrated laser device by employing a single wire, and hence wiring in the semiconductor laser apparatus can be simplified.

In the semiconductor laser apparatus according to the first aspect, the first surface is preferably bonded onto the support substrate through a second adhesive layer, and the third surface is preferably bonded onto the support substrate through a first adhesive layer. According to this structure, the first semiconductor laser device and the integrated laser device can be bonded to the support substrate in a proper order by employing a difference between melting points of the first adhesive layer and the second adhesive layer when materials of the first adhesive layer and the second adhesive layer are different from each other.

In this case, the melting point of the first adhesive layer is preferably higher than the melting point of the second adhesive layer. According to this structure, the melting point of the first adhesive layer is higher than the melting point of the second adhesive layer, and hence also in a case of bonding the first semiconductor laser device to the support substrate through the second adhesive layer after previously bonding the integrated laser device to the support substrate through the first adhesive layer, the integrated laser device can be easily suppressed from being detached from the support substrate when bonding the first semiconductor laser device. Further, a bonding position of the integrated laser device can be easily suppressed from being displaced when bonding the first semiconductor laser device.

In the present invention, a method of manufacturing a semiconductor laser apparatus may be as follows:

In other words, the method of manufacturing the semiconductor laser apparatus according to the present invention comprises steps of forming a first semiconductor laser device including a first surface and a second surface provided on an opposite side to the first surface, forming a second semiconductor laser device including a third surface and a fourth surface provided on an opposite side to the third surface, and so bonding the first surface onto a second region, other than a first region, on one surface of a support substrate that part of the first surface overlaps with the fourth surface after bonding the third surface onto the first region on the one surface of the support substrate.

As hereinabove described, the method of manufacturing the semiconductor laser apparatus according to the present invention comprises the step of so bonding the first surface onto the second region, other than the first region, on the one surface of the support substrate that the part of the first surface of the first semiconductor laser device overlaps with the fourth surface of the second semiconductor laser device after bonding the third surface of the second semiconductor laser device onto the first region on the one surface of the support substrate, whereby the first semiconductor laser device and the second semiconductor laser device can be aligned in the lateral direction on the same one surface of the support substrate, and hence the semiconductor laser apparatus where sizes (thicknesses) of the laser devices are inhibited from increase can be obtained, dissimilarly to a case where a semiconductor layer apparatus is formed by stacking the first semiconductor laser device and the second semiconductor laser device in a thickness direction of the device and bonding the same to each other. When the first semiconductor laser device and the second semiconductor laser device are aligned in the lateral direction on the same one surface of the support substrate, the part of the first surface of the first semiconductor laser device overlaps with the fourth surface of the second semiconductor laser device. Thus, the first semiconductor laser device is not formed such that a width thereof is excessively narrow, and hence an appropriate-sized wire-bonding region for bonding a metal wire can be secured. Consequently, the semiconductor laser apparatus where the metal wire can be easily bonded to the first semiconductor laser device can be obtained.

In the aforementioned method of manufacturing the semiconductor laser apparatus, the step of forming the second semiconductor laser device preferably includes a step of forming the second semiconductor laser device having the third surface on a surface of a growth substrate and further includes a step of forming the fourth surface on the second semiconductor laser device by removing the growth substrate in a region overlapping with at least the first semiconductor laser device to reduce a thickness of the second semiconductor laser device in advance of the step of bonding the first surface onto the second region of the support substrate. According to this structure, a thickness (thickness from the third surface to the fourth surface) of the laser device in a region of the second semiconductor laser device overlapping with the part of the first surface of the first semiconductor laser device is reduced, and hence the first semiconductor laser device and the second semiconductor laser device can be arranged on the same support substrate in a state where the part of the first surface of the first semiconductor laser device easily overlaps with the fourth surface of the second semiconductor laser device. Thus, a height from the support substrate to an active layer of the first semiconductor laser device and a height from the support substrate to an active layer of the second semiconductor laser device can be easily adjusted, and hence the semiconductor laser apparatus where laser beam-emitting points of the both laser devices are closed to each other can be obtained. Thus, when this semiconductor laser apparatus is applied to an optical pickup, light emitted from each of the semiconductor laser devices can be incident at substantially the same angle with respect to (in a direction perpendicular to) a recording surface of an optical disk, a DVD or the like, and hence optical spot quality of the semiconductor laser device in each recording medium can be inhibited from dispersion.

In the aforementioned method of manufacturing the semiconductor laser apparatus, the second semiconductor laser device is preferably made of a group III-V semiconductor including the greatest amount of phosphorus or arsenic as a group element. In a case where the second semiconductor laser device is made of a group III-V semiconductor including the greatest amount of phosphorus or arsenic as a group V element, the second semiconductor laser device is formed employing the growth substrate having low thermal conductivity made of a GaAs substrate or the like, for example, thereafter the second semiconductor laser device is bonded onto the first region of the support substrate while a surface of a laser device layer opposite to the growth substrate serves as a bonded surface (third surface), and thereafter a step of removing the growth substrate is applied. Thus, the semiconductor laser apparatus where heat generated by the second semiconductor laser device can be easily radiated to an external portion through the support substrate by employing the support substrate having higher thermal conductivity than the growth substrate can be obtained.

Further, in the present invention, a method of manufacturing a semiconductor laser apparatus may be as follows:

In other words, the method of manufacturing the semiconductor laser apparatus according to the present invention comprises steps of forming a first semiconductor laser device including a first surface and a second surface provided on an opposite side to the first surface, forming a second semiconductor laser device including a third surface and a fourth surface provided on an opposite side to the third surface and having a lasing wavelength different from the first semiconductor laser device, and so arranging the first semiconductor laser device with respect to the second semiconductor laser device that part of the first surface or the second surface overlaps with the fourth surface after bonding the third surface onto an upper surface of an insulating support substrate formed with a via having a conductive member, wherein the step of forming the first semiconductor laser device includes a step of forming a first electrode of the first semiconductor laser device on the first surface, the step of forming the second semiconductor laser device includes a step of forming a second electrode of the second semiconductor laser device on the third surface and at least either the first electrode or the second electrode is connected to the conductive member.

In the method of manufacturing the semiconductor laser apparatus according to the present invention, as hereinabove described, the first semiconductor laser device is so arranged with respect to the second semiconductor laser device that the part of the first surface or the second surface overlaps with the fourth surface. Thus, when the first semiconductor laser device and the second semiconductor laser device are aligned in a lateral direction on the same upper surface of the support substrate, the semiconductor laser apparatus where a planar size thereof is inhibited from increase can be obtained, because a plurality of the laser devices can be arranged in a state where a plane area of the support substrate is reduced.

As hereinabove described, the method of manufacturing the semiconductor laser apparatus comprises the step of so arranging the first semiconductor laser device on the insulating support substrate that the part of the first surface or the second surface overlaps with the fourth surface after bonding the third surface onto the upper surface of the insulating support substrate formed with the via having the conductive member. As a result, when electrically connecting at least either the first semiconductor laser device or the second semiconductor laser device to the external portion by connecting at least either the first electrode of the first semiconductor laser device or the second electrode of the second semiconductor laser device to the conductive member, wire bonding can be performed by providing an extraction electrode on a lower surface of the support substrate on an opposite side to the surface (upper surface) thereof onto which the laser devices are bonded. Thus, a position where the wire bonding is performed is distanced downwardly from the upper surface, and hence the semiconductor laser apparatus where damage of the laser devices in the wire bonding case be suppressed can be obtained.

In the aforementioned method of manufacturing the semiconductor laser apparatus, the step of forming the second semiconductor laser device preferably includes a step of the second semiconductor laser device having the third surface on a surface of a growth substrate and further includes a step of forming the fourth surface on the second semiconductor laser device by removing the growth substrate in a region overlapping with at least the first semiconductor laser device to reduce a thickness of the second semiconductor laser device in advance of the step of so arranging the first semiconductor laser device with respect to the second semiconductor laser device that the part of the first surface or the second surface overlaps with the fourth surface. According to this structure, a thickness (thickness from the third surface to the fourth surface) of the laser device in a region of the second semiconductor laser device overlapping with the part of the first surface of the first semiconductor laser device is reduced, and hence the first semiconductor laser device and the second semiconductor laser device can be arranged on the same support substrate in a state where the part of the first surface of the first semiconductor laser device easily overlaps with the fourth surface of the second semiconductor laser device. Thus, a height from the support substrate to an active layer of the first semiconductor laser device and a height from the support substrate to an active layer of the second semiconductor laser device can be easily adjusted, and hence the semiconductor laser apparatus where laser beam-emitting points of the both laser devices are closed to each other can be obtained. Thus, when this semiconductor laser apparatus is applied to an optical pickup, light emitted from each of the semiconductor laser devices can be incident at substantially the same angle with respect to (in a direction perpendicular to) a recording surface of an optical disk, a DVD or the like, and hence optical spot quality of the semiconductor laser device in each recording medium can be inhibited from dispersion.

In the aforementioned method of manufacturing the semiconductor laser apparatus, the via preferably includes a first via and a second via so formed in the support substrate as to be connected to at least either the first semiconductor laser device or the second semiconductor laser device, and a first distance between a first facet of the support substrate and a center position of the first via along a direction in which a waveguide of the first semiconductor laser device extends and a second distance between the first facet of the support substrate and a center position of the second via along a direction in which a waveguide of the first semiconductor laser device extends are different from each other. According to this structure, the first via and the second via can be formed deviating to each other along a cavity direction of the laser device, and hence a plurality of the vias can be efficiently provided in the support substrate while increasing diameters of the individual vias even when the support substrate having a small width is employed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view for illustrating a schematic structure of a semiconductor laser apparatus of the present invention;

FIG. 2 is a sectional view for illustrating a schematic manufacturing process of the semiconductor laser apparatus of the present invention;

FIG. 3 is a sectional view for illustrating the schematic manufacturing process of the semiconductor laser apparatus of the present invention;

FIG. 4 is a sectional view for illustrating the schematic manufacturing process of the semiconductor laser apparatus of the present invention;

FIG. 5 is a sectional view for illustrating the schematic manufacturing process of the semiconductor laser apparatus of the present invention;

FIG. 6 is a sectional view for illustrating the schematic manufacturing process of the semiconductor laser apparatus of the present invention;

FIG. 7 is a sectional view showing a structure of a semiconductor laser apparatus according to a first embodiment of the present invention;

FIG. 8 is a top plan view showing the structure of the semiconductor laser apparatus according to the first embodiment of the present invention;

FIG. 9 is a sectional view for illustrating a manufacturing process of the semiconductor laser apparatus according to the first embodiment of the present invention;

FIG. 10 is a sectional view for illustrating the manufacturing process of the semiconductor laser apparatus according to the first embodiment of the present invention;

FIG. 11 is a sectional view for illustrating the manufacturing process of the semiconductor laser apparatus according to the first embodiment of the present invention;

FIG. 12 is a sectional view for illustrating the manufacturing process of the semiconductor laser apparatus according to the first embodiment of the present invention;

FIG. 13 is a sectional view for illustrating the manufacturing process of the semiconductor laser apparatus according to the first embodiment of the present invention;

FIG. 14 is a sectional view showing a structure of a semiconductor laser apparatus according to a first modification of the first embodiment of the present invention;

FIG. 15 is a sectional view showing a structure of a semiconductor laser apparatus according to a second modification of the first embodiment of the present invention;

FIG. 16 is a top plan view showing the structure of the semiconductor laser apparatus according to the second modification of the first embodiment of the present invention;

FIG. 17 is a sectional view showing a structure of a semiconductor laser apparatus according to a second embodiment of the present invention;

FIG. 13 is a top plan view showing the structure of the semiconductor laser apparatus according to the second embodiment of the present invention;

FIG. 19 is a sectional view for illustrating a manufacturing process of the semiconductor laser apparatus according to the second embodiment of the present invention;

FIG. 20 is a sectional view for illustrating the manufacturing process of the semiconductor laser apparatus according to the second embodiment of the present invention;

FIG. 21 is a sectional view showing a structure of a semiconductor laser apparatus according to a third embodiment of the present invention;

FIG. 22 is a top plan view showing the structure of the semiconductor laser apparatus according to the third embodiment of the present invention;

FIG. 23 is a top plan view of a support substrate employed in the semiconductor laser apparatus shown in FIG. 22;

FIG. 24 is a sectional view for illustrating a manufacturing process of the semiconductor laser apparatus according to the third embodiment of the present invention;

FIG. 25 is a sectional view showing a structure of a semiconductor laser apparatus according to a modification of the third embodiment of the present invention;

FIG. 26 is a sectional view showing a structure of a semiconductor laser apparatus according to a fourth embodiment of the present invention;

FIG. 27 is a top plan view showing the structure of the semiconductor laser apparatus according to the fourth embodiment of the present invention;

FIG. 28 is a sectional view for illustrating a manufacturing process of the semiconductor laser apparatus according to the fourth embodiment of the present invention;

FIG. 29 is a sectional view showing a structure of a semiconductor laser apparatus according to a fifth embodiment of the present invention;

FIG. 30 is a top plan view showing the structure of the semiconductor laser apparatus according to the fifth embodiment of the present invention;

FIG. 31 is a sectional view for illustrating a manufacturing process of the semiconductor laser apparatus according to the fifth embodiment of the present invention;

FIG. 32 is a sectional view for illustrating the manufacturing process of the semiconductor laser apparatus according to the fifth embodiment of the present invention;

FIG. 33 is a sectional view showing a structure of a semiconductor laser apparatus according to a sixth embodiment of the present invention;

FIG. 34 is a top plan view showing the structure of the semiconductor laser apparatus according to the sixth embodiment of the present invention;

FIG. 35 is a sectional view for illustrating a manufacturing process of the semiconductor laser apparatus according to the sixth embodiment of the present invention;

FIG. 36 is a sectional view showing a structure of a semiconductor laser apparatus according to a seventh embodiment of the present invention;

FIG. 37 is a sectional view showing a structure of a semiconductor laser apparatus according to a modification of the seventh embodiment of the present invention;

FIG. 38 is a top plan view showing the structure of the semiconductor laser apparatus according to the modification of the seventh embodiment of the present invention;

FIG. 39 is a sectional view showing a structure of a semiconductor laser apparatus according to an eighth embodiment of the present invention;

FIG. 40 is a sectional view showing a structure of a semiconductor laser apparatus according to a modification of the eighth embodiment of the present invention;

FIG. 41 is a sectional view showing a structure of a semiconductor laser apparatus according to a ninth embodiment of the present invention;

FIG. 42 is a top plan view showing the structure of the semiconductor laser apparatus according to the ninth embodiment of the present invention; and

FIG. 43 is a schematic diagram showing a structure of an optical pickup comprising the semiconductor laser apparatus according to a tenth embodiment of the present invention.

### DESCRIPTION OF THE PREFERRED EMBODIMENTS

Embodiments of the present invention are hereinafter described with reference to the drawings.

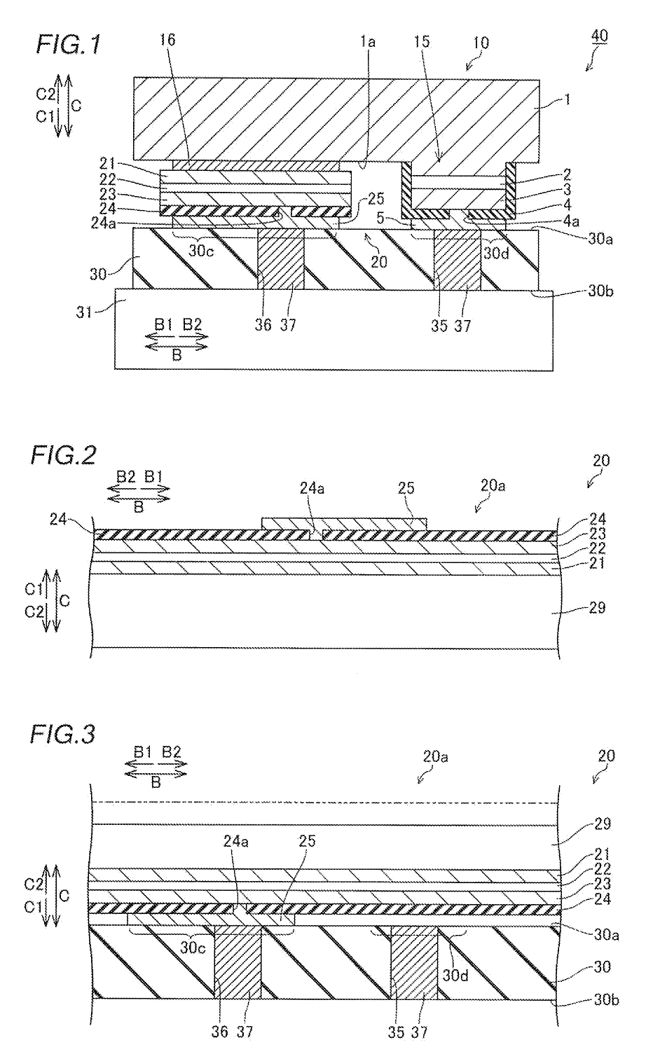

First, a structure of a semiconductor laser apparatus 40 of the present invention is schematically described with reference to FIG. 1 before the embodiments of the present invention are specifically described.

The semiconductor laser apparatus 40 of the present invention comprises a support substrate 30, a first semiconductor laser device 10 bonded onto an upper surface 30a of the support substrate 30 and a second semiconductor laser device 20 bonded onto an upper surface 30a of the support substrate 30 in a state of being adjacent to the first semiconductor laser device 10 in a lateral direction (direction B), as shown in FIG. 1. A lower surface 30b of the support substrate 30 is bonded onto an upper surface of a base 31. The base 31 is an example of the “submount” in the present invention.

The first semiconductor laser device 10 has a structure in which a first conductivity type semiconductor layer 1, an active layer 2 and a second conductivity type semiconductor layer 3 are successively stacked. The active layer 2 comprises a single layer, a single quantum well (SQW) structure, or a multiple quantum well (MQW) structure.

The first conductivity type semiconductor layer 1 comprises a first conductivity type cladding layer or the like having a band gap larger than that of the active layer 2. An optical guiding layer having a band gap between band gaps of the first conductivity type semiconductor layer 1 and the active layer 2 may be provided on an active layer 2 side of the first conductivity type semiconductor layer 1. A carrier blocking layer having a band gap larger than that of the first conductivity type semiconductor layer 1 may be provided between the first conductivity type semiconductor layer 1 and the active layer 2. A first conductivity type contact layer may be provided on an opposite side of the first conductivity type semiconductor layer 1 to the active layer 2.

The second conductivity type semiconductor layer 3 comprises a second conductivity type cladding layer or the like having a band gap larger than that of the active layer 2. An optical guiding layer having a band gap between band gaps of the second conductivity type semiconductor layer 3 and the active layer 2 may be provided on an active layer 2 side of the second conductivity type semiconductor layer 3. A carrier blocking layer having a band gap larger than that of the second conductivity type semiconductor layer 3 may be provided between the second conductivity type semiconductor layer 3 and the active layer 2. A second conductivity type contact layer may be provided on an opposite side of the second conductivity type semiconductor layer 3 to the active layer 2. In this case, a band gap of the second conductivity type contact layer is preferably smaller than that of the second conductivity type cladding layer.

Each semiconductor layer (the first conductivity type semiconductor layer 1, the active layer 2 and the second conductivity type semiconductor layer 3) is made of an AlGaAs-based material, a GaInAs-based material, an AlGaInP-based material, an AlGaInNAs-based material, an AlGaSb-based material, a GaInAsP-based material, a nitride-based semiconductor, an MgZnSSe-based material, a ZnO-based material or the like. GaN, AlN, TnN, BN, TlN or an alloyed semiconductor thereof can be employed as the nitride-based semiconductor.

A substrate may be arranged on the opposite side of the first conductivity type semiconductor layer 1 to the active layer 2. When each semiconductor layer is formed by a wurtzite nitride-based semiconductor, a first conductivity type nitride-based semiconductor substrate or a substrate made of a material other than a nitride-based semiconductor may be employed as the substrate. A first conductivity type α-SiC substrate or the like having a hexagonal structure or a rhombohedral structure can be employed as the substrate made of a material other than a nitride-based semiconductor. The first conductivity type semiconductor layer 1 may include the substrate. The nitride-based semiconductor substrate is the most preferably employed in order to obtain an AlGaInN-based semiconductor layer having the most excellent crystallinity.

A non-polar plane such as a (0001) plane, a (000-1) plane, a (11-20) plane or a (1-100) plane and a semipolar plane such as a (11-22) plane, a (11-2-2) plane, a (1-101) plane or a (1-10-1) plane can be employed as an orientation of a growth surface of the nitride-based semiconductor substrate.

A structure of narrowing current flow in the active layer 2 and forming a waveguide around the active layer 2 is formed in the vicinity of the active layer 2. In this example, an insulating film 4 having an opening 4a is formed on a lower surface of the second conductivity type semiconductor layer 3. A second conductivity side electrode 5 is formed on, the lower surface of the second conductivity type semiconductor layer 3 at the opening 4a and a lower surface of the insulating film 4. The second conductivity side electrode 5 is an example of the “first electrode” in the present invention.

The first semiconductor laser device 10 partly protrudes downwardly (on a C1 side) perpendicularly to a surface of the substrate thereby forming a projecting portion 15, and the active layer 2 to the second conductivity side electrode 5 are formed on a lower surface of the first conductivity type semiconductor layer 1 in the projecting portion 15. A lower surface of a planar portion 1a of the first conductivity type semiconductor layer 1 and a lower surface of the second conductivity side electrode 5 both serving as a lower surface (surface on the C1 side) of the first semiconductor laser device 10 are examples of the “first surface” in the present invention, and an upper surface (surface on a C2 side) of the first conductivity type semiconductor layer 1 is an example of the “second surface” in the present invention. Further, the lower surface of the planar portion 1a is an example of the “first section” in the present invention, and the lower surface of the second conductivity side electrode 5 is an example of the “second section” in the present invention. The “step portion” in the present invention is formed by the projecting portion 15 of the first semiconductor laser device 10 and the planar portion 1a other than the projecting portion 15. The lower surface (the lower surface of the second conductivity side electrode 5) of the first conductivity type semiconductor layer 1 in the projecting portion 15 is an example of the “top portion of the step portion” in the present invention, and the lower surface of the planar portion 1a is an example of the “bottom portion of the step portion” in the present invention. A first conductivity side electrode may be formed on a surface (upper surface) on an opposite side of the first conductivity type semiconductor layer 1 to the active layer 2.

The second semiconductor laser device 20 has a structure in which a first conductivity type semiconductor layer 21, an active layer 22 and a second conductivity type semiconductor layer 23 are successively stacked. The active layer 22 comprises a single layer, an SQW structure or an MQW structure.

The first conductivity type semiconductor layer 21 comprises a first conductivity type cladding layer or the like having a band gap larger than that of the active layer 22. An optical guiding layer having a band gap between band gaps of the first conductivity type semiconductor layer 21 and the active layer 22 may be provided on an active layer 22 side of the first conductivity type semiconductor layer 21. A carrier blocking layer having a band gap larger than that of the first conductivity type semiconductor layer 21 may be provided between the first conductivity type semiconductor layer 21 and the active layer 22. A first conductivity type contact layer may be provided on an opposite side of the first conductivity type semiconductor layer 21 to the active layer 22.

The second conductivity type semiconductor layer 23 comprises a second conductivity type cladding layer or the like having a band gap larger than that of the active layer 22. An optical guiding layer having a band gap between band gaps of the second conductivity type semiconductor layer 23 and the active layer 22 may be provided on an active layer 22 side of the second conductivity type semiconductor layer 23. A carrier blocking layer having a band gap larger than that of the second conductivity type semiconductor layer 23 may be provided between the second conductivity type semiconductor layer 23 and the active layer 22. A second conductivity type contact layer may be provided on an opposite side of the second conductivity type semiconductor layer 23 to the active layer 22. In this case, a band gap of the second conductivity type contact layer is preferably smaller than that of the second conductivity type cladding layer.

Each semiconductor layer (the first conductivity type semiconductor layer 21, the active layer 22 and the second conductivity type semiconductor layer 23) is made of an AlGaAs-based material, a GaInAs-based material, an AlGaInP-based material, an AlGaInNAs-based material, an AlGaSb-based material, a GaInAsP-based material, an MgZnSSe-based material, a ZnO-based material or the like.

The substrate may be arranged on the opposite side of the first conductivity type semiconductor layer 21 to the active layer 22. The first conductivity type semiconductor layer 21 may include the substrate.

A structure of narrowing current flow in the active layer 22 and forming a waveguide around the active layer 22 is formed in the vicinity of the active layer 22. In this example; an insulating film 24 having an opening 24a is formed on a lower surface of the second conductivity type semiconductor layer 23. A second conductivity side electrode 25 is formed on the lower surface of the second conductivity type semiconductor layer 23 at the opening 24a and a lower surface of the insulating film 24. An electrode 16 is formed on an upper surface of the first conductivity type semiconductor layer 21. The second conductivity side electrode 25 is an example of the “second electrode” in the present invention.

The lower surface of the second conductivity side electrode 5 is so bonded onto a region 30d of the support substrate 30 that the lower surface of the planar portion 1a of the first semiconductor laser device 10 overlaps with an upper surface of the electrode 16 of the second semiconductor laser device 20 in a state where a lower surface of the second conductivity side electrode 25 of the second semiconductor laser device 20 is bonded onto a region 30c of the support substrate 30, as shown in FIG. 1. The lower surface of the second conductivity side electrode 25 serving as a lower surface (surface on the C1 side) of the second semiconductor laser device 20 is an example of the “third surface” in the present invention, and the upper surface of the electrode 16 is an example of the “fourth surface” in the present invention. The regions 30c and 30d are examples of the “first region” and the “second region” in the present invention, respectively.

A via 35 penetrating through the support substrate 30 from the region 30d to the lower surface 30b and a via 36 penetrating through the support substrate 30 from the region 30c to the lower surface 30b are formed. The vies 35 and 36 are filled up with conductive members 37 of AuSn or the like.

When forming the vias 33 and 36 in the support substrate 30, an insulating substrate is preferably employed as the support substrate 30. A semiconductor substrate such as single-crystalline insulating Si, insulating SiC or insulating GaAs, or an insulating polycrystalline AlN substrate may be employed, for example. Alternatively, resin may be employed. Alternatively, hardened resin may be employed as the support substrate by solidifying the periphery of a metal wire with resin after bonding the metal wire serving as the via to the second semiconductor laser device 20. Alternatively, an extraction electrode conducting with the conductive members 37 of the vias may be formed on the lower surface 30b. In this case, the extraction electrode may be formed on the base 31 (submount) bonded onto the lower surface 30b.

Neither via 35 nor 36 may be formed in the support substrate 30. In this case, a conductive substrate or the aforementioned insulating substrate may be employed as the support substrate 30. A metal plate such as Cu—W, Al or Fe—Ni, a semiconductor substrate such as single-crystalline n-type or p-type Si, n-type or p-type SiC, n-type or p-type GaAs or n-type ZnO, or a polycrystalline AlN substrate may be employed as the conductive substrate, for example. Alternatively, a conductive resin film in which conductive grains of a metal or the like are dispersed, a composite material of a metal and a metal oxide or the like may be employed, or a composite material of carbon and metal consisting of a graphite particle sintered body impregnated with a metal may be employed. When employing the conductive substrate, an electrode may be formed on a surface (lower surface) on an opposite side of the substrate to the semiconductor layer.

A dielectric multilayer film of low reflectance is formed on a cavity facet (light-emitting surface) on a laser beam-emitting side of each of the first semiconductor laser device 10 and the second semiconductor laser device 20. A dielectric multilayer film of high reflectance is formed on a cavity facet (light-reflecting surface) on a laser beam-reflecting side thereof. A multilayer film made of GaN, AlN, UN, Al₂O₃, SiO₂, ZrO₂, HfO₂, Ta₂O₅, Nb₂O₅, La₂O₃, SiN, AlON and MgF₂, Ti₃O₅, Nb₂O₃ or the like, or a material mixed with these can be employed for the dielectric multilayer film.

The cavity facet emitting a laser beam having relatively large light intensity corresponds to the light-emitting surface, and the cavity facet emitting a laser beam having relatively small light intensity corresponds to the light-reflecting surface.

A material such as polycrystalline AlN, polycrystalline SiC, Si or diamond, having high thermal conductivity can be employed as the base 31. A thickness of the base 31 is larger than a thickness of the support substrate 30.

Next, a manufacturing process of the semiconductor laser apparatus 40 is schematically described with reference to FIGS. 1 to 6.

As shown in FIG. 2, a semiconductor device layer constituted by the first conductivity type semiconductor layer 21, the active lever 22 and the second conductivity type semiconductor layer 23 is formed on an upper surface of a substrate 29. Further, the insulating film 24 is formed on a surface of the second conductivity type semiconductor layer 23. The second conductivity side electrode 25 covers the opening 24a and the insulating film 24 in the vicinity of the opening 24a, thereby preparing a second semiconductor laser device substrate 20a. The substrate 29 is an example of the “growth substrate” in the present invention.

On the other hand, the vias 35 and 36 penetrating from the upper surface 30a to the lower surface 30b are formed in a prescribed region of the support substrate 30 shown in FIG. 3, and thereafter the vias 35 and 36 are filled up with the conductive members 37.

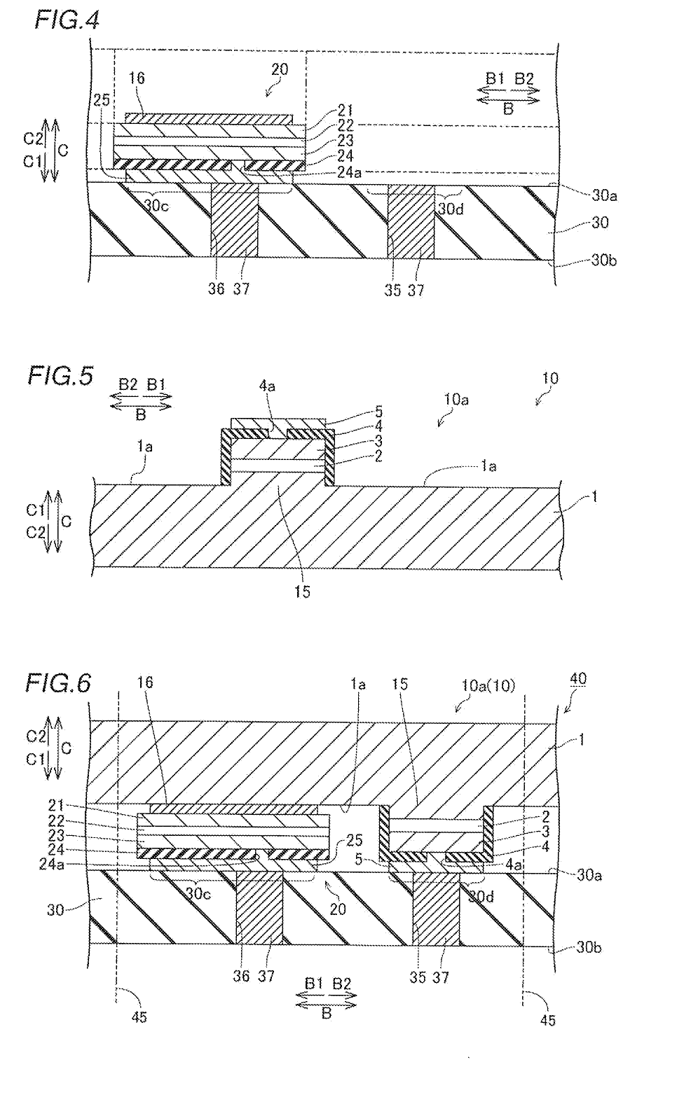

Then, the surface lower surface) of the second conductivity side electrode 25 of the second semiconductor laser device substrate 20a and the support substrate 30 are opposed to each other to bond these substrates to each other, as shown in FIG. 3. At this time, the lower surface of the second conductivity side electrode 25 is bonded at a position where the via 36 is formed. Next, the substrate 29 is polished or etched thereby reducing a thickness of the substrate 29, as shown in FIG. 3. Wet etching, dry etching or the like is employed as etching. The substrate 29 having a reduced thickness may remain on a surface of the first conductivity type semiconductor layer 21 or the substrate 29 may be completely removed as shown in FIG. 4.

Thereafter, the second semiconductor laser device substrate 20a (constituted only by the semiconductor device layer in FIG. 4) is partly removed to leave the opening 24a, as shown in FIG. 4, thereby forming the second semiconductor laser device 20 having a prescribed width in a direction (direction B) substantially orthogonal to a direction (perpendicular to the plane of FIG. 4) in which a cavity extends in a plane of the substrate 29 (see FIG. 3) and exposing the region 30d having the via 35 of the support substrate 30 under the removed semiconductor device layer. An unnecessary portion of the semiconductor device layer may be separated by scribing the second semiconductor laser device substrate 20a (see FIG. 3) along a cavity direction or may be removed by wet etching, dry etching or the like. Thereafter, the electrode 16 is formed on the surface of the first conductivity type semiconductor layer 21.

On the other hand, in the first semiconductor laser device 10, a semiconductor device layer constituted by the first conductivity type semiconductor layer 1, the active layer 2 and the second conductivity type semiconductor layer 3 is first formed, as shown in FIG. 5. Etching such as dry etching is performed from the second conductivity type semiconductor layer 3 up to an intermediate portion of the first conductivity type semiconductor layer 1 while leaving the vicinity of a portion becoming the opening 4a, thereby forming the projecting portion 15 including the active layer 2. Then, the insulating film 4 is formed on the surface of the second conductivity type semiconductor layer 3. The second conductivity side electrode 5 is formed to cover the opening 4a and the insulating film 4 in the vicinity of the opening 4a, thereby preparing a first semiconductor laser device substrate 10a.

Thereafter, as shown in FIG. 6, an upper surface (the upper surface of the first conductivity type semiconductor layer 21) of the second semiconductor laser device 20 and the electrode 16 are opposed to each other and the region 30d while the projecting portion 15 (second conductivity side electrode 5) are opposed to each other, thereby bonding the wafers to each other. At this time, the via 35 and the lower surface of the second conductivity side electrode 5 are bonded onto each other.

Then, the cavity facet of each of the first semiconductor laser device 10 and the second semiconductor laser device 20 is formed by cleaving the wafer in the form of a bar to have a prescribed cavity length. Thereafter, the dielectric multilayer film of low reflectance is formed on the cavity facet on the light-emitting side of each of the first semiconductor laser device 10 and the second semiconductor laser device 20 while the dielectric multilayer film of high reflectance is formed on the cavity facet on the light-reflecting side thereof. Finally, the bar is divided into devices in the cavity direction along device division lines 45 in FIG. 6, thereby forming a plurality of chips of the semiconductor laser apparatus 40 (see FIG. 1).

As hereinabove described, the lower surface of the second conductivity side electrode 5 is so bonded onto the region 30d of the support substrate 30 that the lower surface of the planar portion 1a of the first semiconductor laser device 10 overlaps with the upper surface of the first conductivity type semiconductor layer 21 of the second semiconductor laser device 20. Thus, the first semiconductor laser device 10 and the second semiconductor laser device 20 can be aligned in the lateral direction (direction B) on the same support substrate 30, and hence sizes (thicknesses in a direction C) of the laser devices can be inhibited from increase, dissimilarly to a case where a semiconductor layer apparatus is formed by stacking the first semiconductor laser device 10 and the second semiconductor laser device 20 in a thickness direction of the device and bonding the same to each other. When the first semiconductor laser device 10 and the second semiconductor laser device 20 are aligned in the lateral direction on the same support substrate 30, the lower surface of the planar portion 1a of the first semiconductor laser device 10 is arranged to overlap with the upper surface of the first conductivity type semiconductor layer 21 of the second semiconductor laser device 20. Thus, the first semiconductor laser device 10 (first conductivity type semiconductor layer 1) is not formed such that a width thereof in the direction B is excessively narrow, and hence an appropriate-sized wire-bonding region (the upper surface of the first conductivity type semiconductor layer 1) for bonding a metal wire can be secured. Consequently, the metal wire can be easily bonded to the first semiconductor laser device 10.

The first semiconductor laser device 10 is so arranged with respect to the second semiconductor laser device 20 that the lower surface of the planar portion 1a overlaps with the upper surface of the electrode 16. Thus, a plane area of the support substrate 30 can be further reduced, and hence a planar size of the semiconductor laser apparatus 40 can be inhibited from increase.

The lower surface of the second conductivity side electrode 25 is bonded onto the region 30c of the support substrate 30, and thereafter the substrate 29 in a region overlapping with the first semiconductor laser device 10 is removed to reduce a thickness (height) of the second semiconductor laser device 20 before bonding the second conductivity side electrode 5 of the first semiconductor laser device 10 onto the region 30d, whereby the upper surface of the first conductivity type semiconductor layer 21 overlapping with the lower surface of the planar portion 1a of the first semiconductor laser device 10 is formed on the second semiconductor laser device 20. Thus, a thickness is thickness from the lower surface of the second conductivity side electrode 25 to the upper surface of the first conductivity type semiconductor layer 21) of the laser device in a region overlapping with the lower surface of the planar portion 1a is reduced, whereby the first semiconductor laser device 10 and the second semiconductor laser device 20 can be arranged on the same support substrate 30 in a state where the lower surface of the planar portion 1a easily overlaps with the upper surface of the first conductivity type semiconductor layer 21. Consequently, a height from the support substrate 30 to the active layer 2 of the first semiconductor laser device 10 and a height from the support substrate 30 to the active layer 22 of the second semiconductor laser device 20 can be easily adjusted, and hence the semiconductor laser apparatus 40 where respective laser beam-emitting points of the laser devices are closed to each other can be obtained.

In a case where the semiconductor device layer is partly removed by etching to leave the opening 24a in the second semiconductor laser device substrate 20a bonded to the support substrate 30 and the region 30d is exposed under the removed semiconductor device layer, it is not necessary to provide a portion of kerf loss for dividing the device by scribing or dicing in the second semiconductor laser device substrate 20a as compared with a case where the same process is performed by scribing or dicing. Therefore, a width (in the direction B) of the second semiconductor laser device 20 can be reduced, whereby the laser beam-emitting point of the second semiconductor laser device 20 can be arranged closer to the first semiconductor laser device 10.

In the first semiconductor laser device 10, the lower surface of the planar portion 1a of the first conductivity type semiconductor layer 1 overlaps with the upper surface of the electrode 16 while the lower surface (the lower surface of the second conductivity side electrode 5) of the first conductivity type semiconductor layer 1 in the projecting portion 15 is bonded onto the region 30d. Thus, the first semiconductor laser device 10 can be easily bonded onto the region 30d by effectively employing a stepped shape of the projecting portion 15 in a state where the planar portion 1a of the first semiconductor laser device 10 overlaps with the upper surface of the electrode 16 of the second semiconductor laser device 20.

The thickness (in the direction C) of the second semiconductor laser device 20 is not more than a height from the planar portion 1a of the first semiconductor laser device 10 to the lower surface (the lower surface of the second conductivity side electrode 5) of the first conductivity type semiconductor layer 1 in the projecting portion 15. Thus, the second semiconductor laser device 20 can be easily arranged between the region 30a of the support substrate 30 and the planar portion 1a of the first semiconductor laser device 10.

The projecting portion 15 protruding downwardly from the surface of the substrate is formed by etching on the first semiconductor laser device 10 (or the first semiconductor laser device substrate 10a). Thus, it is not necessary to provide a portion of kerf loss for dicing the first semiconductor laser device 10 (or the first semiconductor laser device substrate 10a) as compared with a case where the same process is performed by dicing or the like, and hence the width of the first semiconductor laser device 10 can be reduced, whereby the laser beam-emitting point of the first semiconductor laser device 10 can be arranged closer to the second semiconductor laser device 20. In a case where the first semiconductor laser device 10 is made of a hexagonal nitride-based semiconductor in particular, because cleavage directions disagree with device division directions, the device division surfaces cannot be formed by cleavage. Thus, straightness of the division lines is extremely bad, and hence it is necessary to secure a large portion of kerf loss in the first semiconductor laser device 10.

The projecting portion 15 protruding downwardly (on the C1 side) from the surface of the substrate is formed on the first semiconductor laser device 10, and a lower surface (the lower surface of the second conductivity side electrode 5) of the semiconductor device layer formed in this projecting portion 15 is bonded onto the region 30d of the support substrate 30. Thus, the first semiconductor laser device 10 can be so arranged that the waveguide (laser beam-emitting point) formed in the active layer 2 over the opening 4a is close to the upper surface of the support substrate 30. In other words, in FIG. 1, the height from the lower surface of the support substrate 30 to the active layer 22 of the second semiconductor laser device 20 and the height from the lower surface of the support substrate 30 to the active layer 2 of toe first semiconductor laser device 10 can approximate each other, and hence the laser beam-emitting points can be aligned in the lateral direction. A distance between the support substrate 30 and the laser beam-emitting point (waveguide) of the first semiconductor laser device 10 is reduced, whereby heat of the first semiconductor laser device 10 can be easily radiated.

The vias 35 and 36 are formed in the insulating support substrate 30. The vias 35 and 36 are penetrating through the support substrate 30 from the lower surface 30b to the upper surface 30a onto which the first semiconductor laser device 10 and the second semiconductor laser device 20 are bonded. The vias 35 and 36 are filled up with the conductive members 37. The second conductivity side electrodes 5 and 25 are connected to the conductive members 37 of the vias 35 and 36 respectively. Thus, wire bonding can be performed by providing an extraction electrode on a lower surface 30b side of the support substrate 30 opposite to a side (upper surface 30a side) bonded with the laser devices when electrically connecting the first semiconductor laser device 10 and the second semiconductor laser device 20 with an external portion. In other words, a position where the wire bonding is performed can be distanced downwardly (on the C1 side) from the upper surface 30a of the support substrate 30 onto which the laser devises are bonded, and hence damage of the laser devices in the wire bonding can be suppressed. Further, it is not necessary to perform wire bonding on the upper surface 30a side, and hence the widths of the laser devices can be narrowed.

Embodiments of the present invention are now described.

### First Embodiment

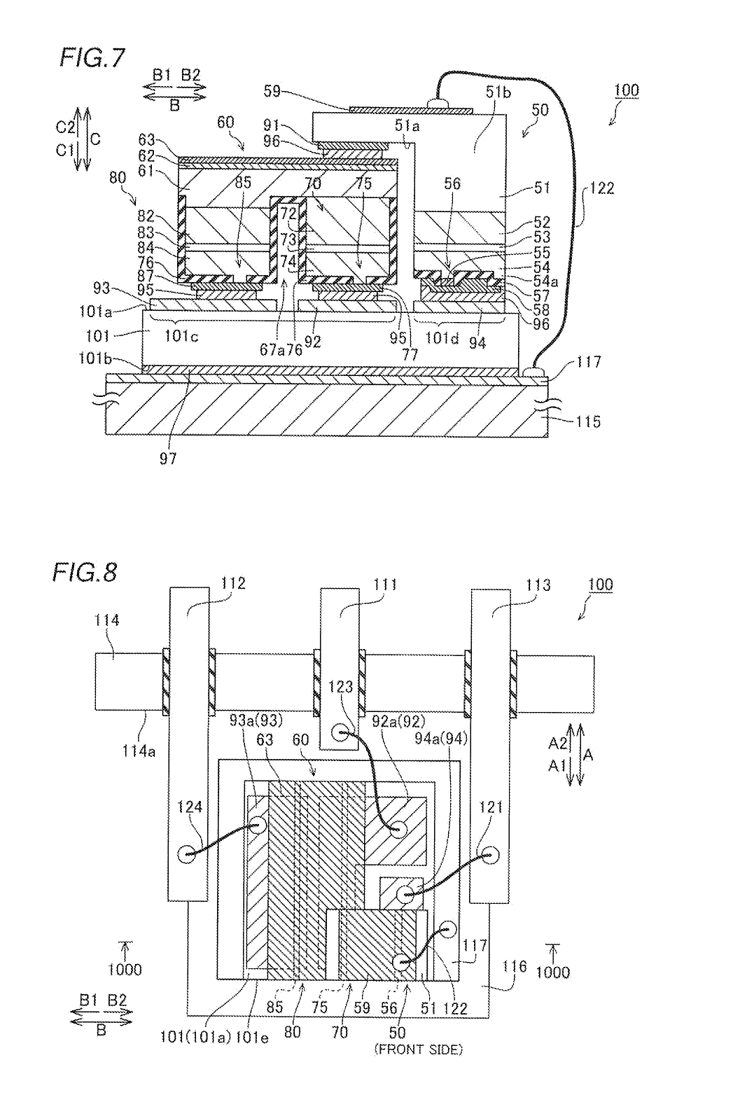

A structure of a semiconductor laser apparatus 100 according to a first embodiment of the present invention is described with reference to FIGS. 7 and 8. FIG. 7 shows a section taken along the line 1000-1000 in FIG. 8.

The semiconductor laser apparatus 100 has a structure in which a blue-violet semiconductor laser device 50 and a two-wavelength laser device 60 are bonded onto a surface of a support substrate 101 made of insulating Si to be adjacent to each other in a lateral direction (direction B), as shown in FIG. 7. The blue-violet semiconductor laser device 50 has a lasing wavelength of about 405 nm and a cavity length of about 800 μm. The two-wavelength laser device 60 is monolithically formed with a red semiconductor laser device 70 having a lasing wavelength of about 650 nm and a cavity length of about 1.5 mm and an infrared semiconductor laser device 80 having a lasing wavelength of about 780 nm and a cavity length of about 1.5 mm. The blue-violet semiconductor laser device 50 is an example of, the “first semiconductor laser device” in the present invention. The two-wavelength laser device 60 is an example of the “integrated laser device” in the present invention. One of either the red semiconductor laser device 70 or the infrared semiconductor laser device 80 is an example of the “second semiconductor laser device” in the present invention. The other of either the red semiconductor laser device 70 or the infrared semiconductor laser device 80 is an example of the “third semiconductor laser device” in the present invention.

In the blue-violet semiconductor laser device 50, an n-type cladding layer 52 made of Si-doped n-type Al_{0.05}Ga_{0.95}N, an active layer 33 having an MQW structure formed by alternately staking quantum well layers made of InGaN having a higher In composition and barrier layers made of InGaN having a lower In composition and a p-type cladding layer 54 made of Mg-doped p-type Al_{0.05}Ga_{0.95}N are formed on a lower surface of an n-type GaN substrate 51 having a width (maximum width in the direction B) of about 100 μm and a thickness (maximum thickness in a direction C) of about 100 μm. The lower surface of the n-type Ga substrate 51 has a projecting portion 51b protruding downwardly in a direction C1, having a width of about 70 μm and a planar portion 51a other than the projecting portion 51b, having a width of about 30 μm. The semiconductor device layer constituting the aforementioned laser device portion is formed on a lower surface of the projecting portion 51b.

The p-type cladding layer 54 has a jut portion formed at a position (position lying a distance of about 10 μm inward from a side surface of the projecting portion 51b on a B1 side toward an opposite side (B2 side) to the two-Wavelength laser device 60) deviating to the two-wavelength laser device 60 (51 side) from a central portion of the projecting portion 51b. The p-type cladding layer 54 has planar portions extending on both sides (in a direction B) of the jut portion. The p-type cladding layer 54 is formed with a support portion 54a protruding downwardly on an end of the planar portion on the B2 side. A p-side ohmic electrode layer 55 including a Pd layer, a Pt layer and an Au layer successively from the side closer to the p-type cladding layer 54 is formed on the jut portion of the p-type cladding layer 54. This jut portion of the p-type cladding layer 54 and the p-side ohmic electrode layer 55 form a ridge 56 for constituting a waveguide. The ridge 56 has a width of about 1.5 μm in the direction B and extends along a cavity direction (direction A in FIG. 8). A thickness from a lower surface of the planar portion 51a to a top portion (a lower surface of the p-side ohmic electrode layer 55) of the ridge 56 is about 8 μm. The directions A and B are examples of the “first direction” and the “second direction” in the present invention, respectively.

A current blocking layer 57 made of SiO₂ covers lower surfaces of the planar portions (including the support portion 54a) of the p-type cladding layer 54 and side surfaces of the ridge 56. A p-side pad electrode 58 made of an Au layer or the like covers upper surfaces of the ridge 56 and the current blocking layer 57. The lower surface of the p-side pad electrode 53 and the lower surface (a surface on a C1 side) of the planar portion 51a are examples of the “first surface” in the present invention. The upper surface (a surface on a C2 side) of the n-type GaN substrate 51 is an example of the “second surface” in the present invention. The lower surface of the planar portion 51a is an example of the “first section” in the present invention. The lower surface of the p-side pad electrode 53 is an example of the “second section” in the present invention.

An n-side electrode 59 including a Pt layer, a Pd layer and an Au layer successively from the side closer to the n-type GaN substrate 51 is formed on the upper surface of the n-type GaN substrate 51. A pad electrode 91 extending along the cavity direction in the form of a strip is formed on the surface of the planar portion 51a. The pad electrode 91 includes a Pt layer, a Pd layer and an Au layer successively from the side closer to the s-type GaN substrate 51.

As shown in FIG. 7, the red semiconductor laser device 70 having a width about 30 μm on the B2 side and the infrared semiconductor laser device 80 having a width of about 30 μm on the B1 side are formed through a recess portion 67a having a width of about 5 μm on a lower surface of an n-type contact layer 61 made of Si-doped GaAs, thereby forming the two-wavelength laser device 60. The two-wavelength laser device 60 has a device width (maximum width) of about 65 μm.

In the red semiconductor laser device 70, an n-type cladding layer 72 made of AlGaInP, having a thickness of about 2.5 μm, an active layer 73 having an MQW structure formed by alternately staking quantum well layers made of GaInP and barrier layers made of AlGaInP and a p-type cladding layer 74 made of AlGaInP, having a thickness of about 1 μm are formed on the lower surface of the n-type contact layer 61.

The p-type cladding layer 74 has a jut portion at a position (position lying a distance of about 10 μm inward from a side surface of the red semiconductor laser device 70 closer to the blue-violet semiconductor laser device 50 (on the B2 side) toward an opposite side (B1 side) to the blue-violet semiconductor laser device 50) slightly deviating to the B2 side from a substantially central portion of the device. The p-type cladding layer 74 has planar portions extending on both sides (in the direction B) of the jut portion. This jut portion of the p-type cladding layer 74 forms a ridge 75 for constituting a waveguide. The ridge 75 has a width of about 2 μm in the direction B and extends along the cavity direction (direction A in FIG. 8).

A current blocking layer 76 made of SiC covers side surfaces of the p-type cladding layer 74 to the n-type cladding layer 72, the partial lower surface of the n-type contact layer 61 and a lower surface of the p-type cladding layer 74 except the ridge 75. A p-side pad electrode 77 prepared by stacking a Cr layer having a thickness of about 10 nm and an Au layer having a thickness of about 2.2 μm covers lower surfaces of the ridge 75 (p-type cladding layer 74) and the current blocking layer 76.

In the infrared semiconductor laser device 80, an n-type cladding layer 82 made of AlGaAs, having a thickness of about 2 μm, an active layer 83 having an MQW structure formed by alternately staking quantum well layers made of AlGaAs having a lower Al composition and barrier layers made of AlGaAs having a higher Al composition and a p-type cladding layer 84 made of AlGaAs, having a thickness of about 1 μm are formed on the lower surface of the n-type contact layer 61.

The p-type cladding layer 34 has a jut portion at a position (position lying a distance of about 10 μm inward from a side surface of the infrared semiconductor laser device 80 on the B2 side toward the B1 side) slightly deviating to the B2 side from a substantially central portion of the device. The p-type cladding layer 84 has planar portions extending on both sides of the jut portion. This jut portion of the p-type cladding layer 84 forms a ridge 85 for constituting a waveguide. The ridge 85 has a width of about 3 μm in the direction B and extends along the cavity direction (direction A in FIG. 8).

The current blocking layer 76 covers side surfaces of the p-type cladding layer 84 to the n-type cladding layer 82, a partial side surface of the n-type contact layer 61 on the B2 side and a lower surface of the p-type cladding layer 84 except the ridge 85. A p-side pad electrode 87 prepared by stacking a Cr layer having a thickness of about 10 nm and an Au layer having a thickness of about 2.2 μm covers lower surfaces of the ridge 85 (p-type cladding layer 34) and the current blocking layer 76.

An n-side ohmic electrode 62 prepared by successively stacking an AuGe layer and an Ni layer from a lower layer toward an upper layer is formed on an upper surface of the n-type contact layer 61. An n-side pad electrode 63 made of an Au layer is formed on an upper surface of the n-side ohmic electrode 62.

A thickness of the n-type contact layer 61 of the two-wavelength laser device 60 is about 1 μm on a portion where the infrared semiconductor laser device 80 is formed and about 0.5 μm on the remaining portion. Thus, lower surfaces of the p-side pad electrodes 77 and 87 are on substantially identical planes. A thickness from the lower surfaces of the p-side pad electrodes 77 and 87 to an upper surface of the n-side pad electrode 63 is about 6 μm.

As shown in FIG. 8, pad electrodes 92, 93 and 94 each are formed through patterning on the surface of the substantially rectangular support substrate 101 having a width of about 300 μm in the direction B to have a prescribed shape in plan view. As shown in FIGS. 7 and 8, on a region 101c of the support substrate 101, bonded with the two-wavelength laser device 60, the pad electrode 92 is arranged at a position opposed to the p-side pad electrode 77 of the red semiconductor laser device 70 while the pad electrode 93 is arranged at a position opposed to the p-side pad electrode 87 of the infrared semiconductor laser device 80. The pad electrode 94 is arranged at a position (region 101d) opposed to the p-side pad electrode 58 of the blue-violet semiconductor laser device 50, next (on the B2 side) to the pad electrode 92. The regions 101c and 101d are examples of the “first region” and the “second region” in the present invention, respectively. The pad electrodes 92, 93 and 94 are an example of the “extraction electrode” in the present invention.

As shown in FIG. 7, the lower surface of the p-side pad electrode 58 is so bonded onto the pad electrode 94 through a conductive adhesive layer 96 that the planar portion 51a overlaps with the upper surface of the n-side pad electrode 63 in a state where the lower surfaces the p-side pad electrodes 77 and 87 are bonded onto the pad electrodes 92 and 93 through conductive adhesive layers 95, respectively. At this time, the n-side pad electrode 63 and the pad electrode 91 are bonded to each other through a conductive adhesive layer 96. The lower surfaces of the p-side pad electrodes 77 and 87 are examples of the “third surface” in the present invention, and the upper surface of the n-side pad electrode 63 is an example of the “fourth surface” in the present invention. The conductive adhesive layers 95 and 96 are examples of the “first adhesive layer” and the “second adhesive layer” in the present invention, respectively.

As shown in FIG. 8, the cavity length of the blue-violet semiconductor laser device 50 is shorter than a cavity length of the two-wavelength laser device 60. The blue-violet semiconductor laser device 50 and the two-wavelength laser device 60 are so bonded to the support substrate 101 that cavity facets thereof on a light-emitting side (an A1 side) are aligned on the same plane (facet 101e). An upper surface 101a of the support substrate 101 is exposed with a width of about 120 μm on a B1 side of the two-wavelength laser device 60, and the upper surface 101a of the support substrate 101 is exposed with a width of about 40 μm on a B2 side of the blue-violet semiconductor laser device 50. The upper surface 101a onto which the two-wavelength laser device 60 and the blue-violet semiconductor laser device 50 are not bonded is exposed on a B2 side of the two-wavelength laser device 60 and an A2 side of the blue-violet semiconductor laser device 50. The upper surface 101a of this portion is an example of the “area other than the second region” in the present invention.

The conductive adhesive layers 95 are made of Au—Sn (about 20% of Sn) solder having a melting point of about 280° C. The conductive adhesive layers 96 are made of Au—Sn (about 90% of Sn) solder having a melting point of about 210° C.

The semiconductor laser apparatus 100 comprises a protruding block 116 and a stem 114. The stem 114 is provided with three lead terminals 111, 112 and 113 and another lead terminal (not shown). The three lead terminals 111, 112 and 113 are insulated from the protruding block 116 and penetrating through a bottom portion 114a. The another lead terminal is electrically conducting with the protruding block 116 and the bottom portion 114a.

As shown in FIG. 7, the support substrate 101 is electrically connected to a base 115 made of a conductive material such as AlN through a conductive adhesive layer 97 while a lower surface of the base 115 is fixed onto an upper surface of the protruding block 116 (see FIG. 8) through a conductive adhesive layer (not shown).

As shown in FIG. 8, the pad electrode 94 extends to an opposite side (an A2 side) to the light-emitting side from between the blue-violet semiconductor laser device 50 and the support substrate 101 so as to be exposed from the blue-violet semiconductor laser device 50. The p-side pad electrode 58 of the blue-violet semiconductor laser device 30 is connected to the lead terminal 113 through a metal wire 121 wire-bonded to a wire-bonding portion 94a of the pad electrode 94. The n-side electrode 59 is connected to an electrode layer 117 formed on a surface of the base 115 through a metal wire 122. The pad electrode 92 partly protrudes and extends to the B2 side from between the red semiconductor laser device 70 and the support substrate 101 so as to be exposed from the red semiconductor laser device 70. The p-side pad electrode 77 of the red semiconductor laser device 70 is connected to the lead terminal 111 through a metal wire 123 wire-bonded to a wire-bonding portion 92a of the pad electrode 92. The pad electrode 93 extends to the B1 side from between the infrared semiconductor laser device 80 and the support substrate 101 so as to be exposed from the infrared semiconductor laser device 80. The p-side pad electrode 87 of the infrared semiconductor laser device 80 is connected to the lead terminal 112 through a metal wire 124 wire-bonded to a wire-bonding portion 93a of the pad electrode 93. As shown in FIG. 7, the n-side pad electrode 63 is electrically connected to the pad electrode 91 through the conductive adhesive layer 96. Thus, the semiconductor laser apparatus 100 is formed in a state (cathode-common) where the p-side pad electrodes (58, 77 and 87) are electrically connected to the lead terminals insulated from each other while the n-side electrodes (59 and 63) are electrically connected to a common cathode terminal.

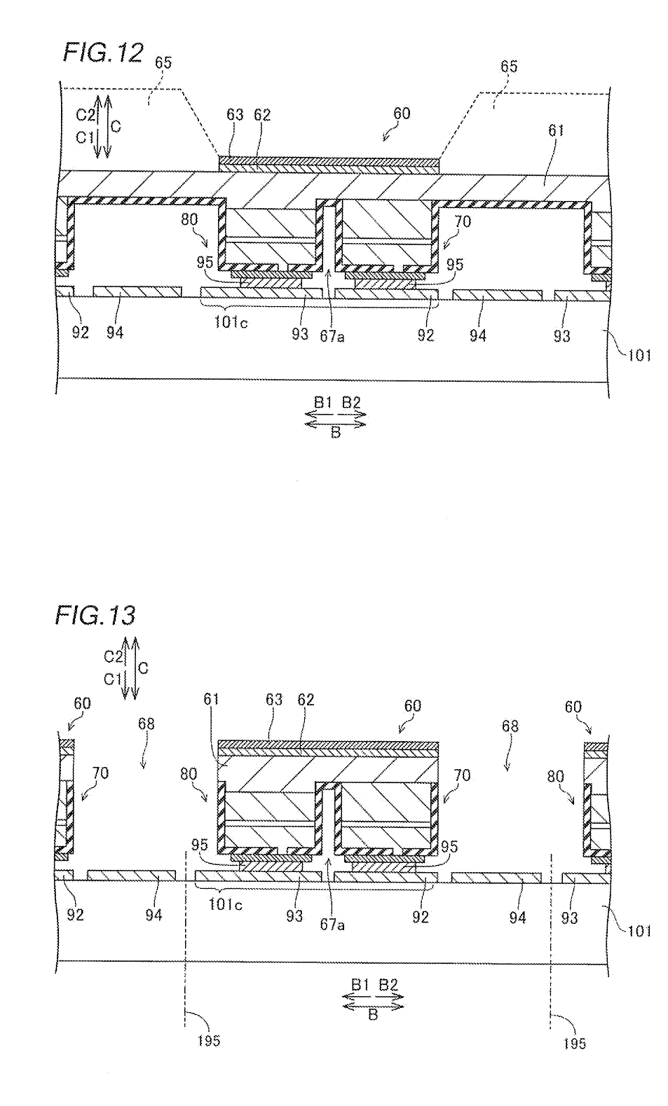

A manufacturing process of the semiconductor laser apparatus 100 is now described with reference to FIGS. 7 to 13. FIGS. 12 and 13 show a state of a section taken along the line 1000-1000 in FIG. 8 in the manufacturing process.

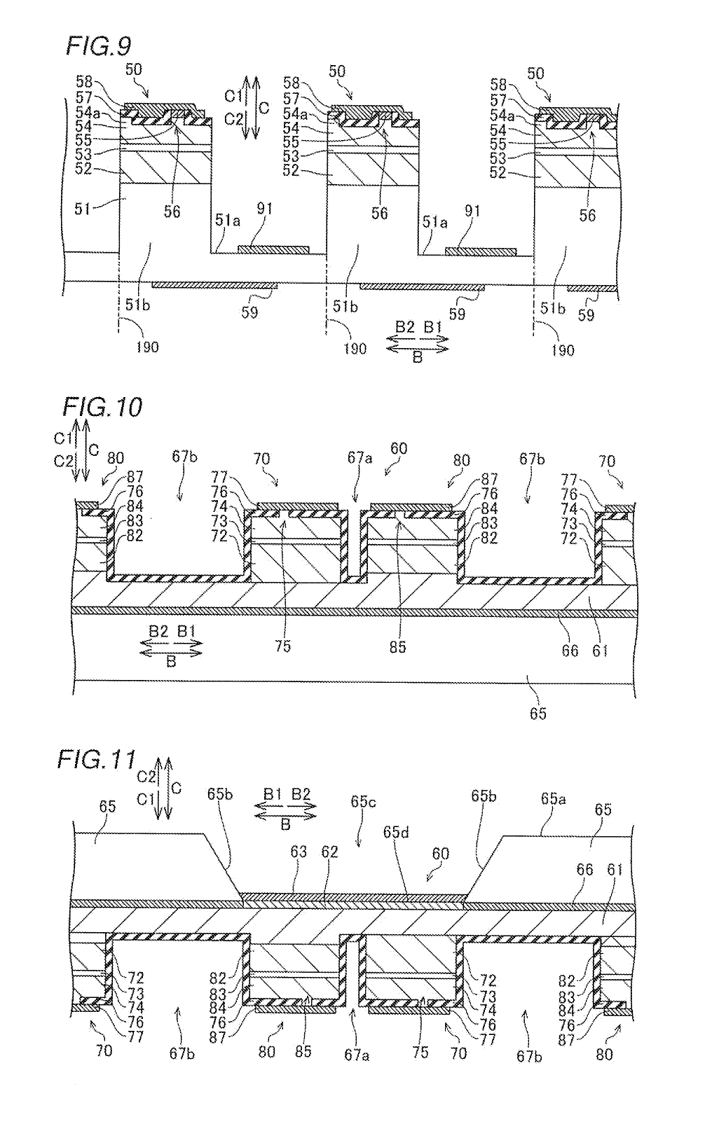

In the manufacturing process of the semiconductor laser apparatus 100, the n-type cladding layer 52, the active layer 53 and the p-type cladding layer 54 are successively formed on the upper surface of the n-type GaN substrate 51 by metalorganic chemical vapor deposition (MOCVD), as shown in FIG. 9. Thereafter, etching such as dry etching is performed from a surface of the p-type cladding layer 54 to the n-type GaN substrate 51, thereby leaving the semiconductor device layers forming the laser devices only on the projecting portions 51b of the n-type GaN substrate 51.

After forming the ridges 56 on the semiconductor device layers, the current blocking layers 57, the p-side ohmic electrode layers 55 and the p-side pad electrodes 58 are formed. The pad electrodes 91 extending along the cavity direction of the blue-violet semiconductor laser devices 50 in the form of strips are formed on the planar portions 51a of the n-type GaN substrate 51 by vacuum evaporation, thereby preparing a wafer formed with the blue-violet semiconductor laser devices 50 excluding the n-side electrodes 59 (see FIG. 7).

Then, the lower surface of the n-type GaN substrate 51 is so polished that the n-type GaN substrate 51 has a prescribed thickness, and thereafter the n-side electrodes 59 are formed on the lower surface of the n-type GaN substrate 51 by vacuum evaporation. Thereafter, the wafer is cleaved in the form of a bar to have a prescribed cavity length thereby forming the cavity facets of the blue-violet semiconductor laser devices 50, and the bar is divided into devices in the cavity direction along device division lines 190 in FIG. 9 thereby forming a plurality of chips of the blue-violet semiconductor laser devices 50.

Next, an etching stopper layer 66 made of A_{0.5}Ga_{0.5}As, having a thickness of about 0.1 μm and the n-type contact layer 61 are stacked on an upper surface of a GaAs substrate 65 in this order, as shown in FIG. 10. Thereafter, the red semiconductor laser device 70 and the infrared semiconductor laser device 80 are formed on the upper surface of the n-type contact layer 61 to separate from each other at an interval of about 5 μm, thereby preparing a wafer of the two-wavelength laser device 60. The GaAs substrate 65 is an example of the “growth substrate” in the present invention.

Specifically, the n-type cladding layer 82, the active layer 83 and the p-type cladding layer 84 are successively formed on the upper surface of the n-type contact layer 61. Thereafter, the n-type contact layer 61 is partly exposed by etching the p-type cladding layer 84 to part of the n-type contact layer 61 by a depth of about 0.5 μm, and the n-type cladding layer 72, the active layer 73 and the p-type cladding layer 74 are successively formed on part of the exposed portion while leaving regions for forming the recess portion 67a and a recess portion 67b. Then, the ridges 75 and 85 and the current blocking layer 76 are formed in the infrared semiconductor laser device 80 and the red semiconductor laser device 70. Thereafter, the p-side pad electrode 77 is formed to cover upper surfaces of the ridge 75 and the current blocking layer 76 by vacuum evaporation. The p-side pad electrode 87 is formed to cover upper surfaces of the ridge 85 and the current blocking layer 76.

As shown in FIG. 11, a recess portion 65c having side surfaces 65b is formed in a prescribed region of an opposite surface 65a of the GaAs substrate 65 to the n-type contact layer 61 by wet etching with an ammonia-based etchant. At this time, the etching is stopped at an interface between the etching stopper layer 66 and the n-type contact layer 61. Thereafter, the etching stopper layer 66 exposed at a bottom portion of the recess portion 65c is removed by wet etching with hydrofluoric acid, hydrochloric acid or the like, thereby exposing the upper surface (bottom surface 65d) of the n-type contact layer 61. Then, the n-side ohmic electrode 62 and the n-side pad electrode 63 are successively formed on the bottom surface 65d of the recess portion 65c by vacuum evaporation.

Thereafter, heat treatment is performed in a nitrogen atmosphere to alloy the n-side ohmic electrode 62 and the n-type contact layer 61.

Thereafter, the support substrate 101 and the wafer formed with the two-wavelength laser device 60 are bonded to each other, as shown in FIG. 12. At this time, the support substrate 101 and the wafer are bonded through the conductive adhesive layers 95 while opposing the p-side pad electrode 77 and the pad electrode 92 to each other and the p-side pad electrode 37 and the pad electrode 93 to each other.

Thereafter, wet etching is performed with an ammonia-based etchant thereby removing the overall GaAs substrate 65 (indicated by a broken line), as shown in FIG. 12. The overall etching stopper layer 66 (see FIG. 11) is removed by wet etching with hydrofluoric acid, hydrochloric acid or the like. Thus, only the n-type ohmic electrode 62 and the n-side pad electrode 63 remain on the n-type contact, layer 61. Then, the n-type contact layer 61 in regions (regions formed with the recess portions 67b) not formed with the device structures of the red semiconductor laser device 70 and the infrared semiconductor laser device 80 is removed by scribing, wet etching or the like, thereby forming recess portions 68 each having a width of about 235 μm for bonding the blue-violet semiconductor laser device 50 above the pad electrode 94 in a later step, as shown in FIG. 13. Thus, the wafer is separated in the direction B, and a plurality of the two-wavelength laser devices 60 each having a width of about 65 μm in the direction B are formed.

Thereafter, the wafer is cleaved in the form of a bar to have the prescribed cavity length, thereby forming the cavity facets of each semiconductor laser device. Then, a dielectric multilayer film of low reflectance is formed on the cavity facet on the light-emitting side while a dielectric multilayer film of high reflectance is formed on the cavity facet on the light-reflecting side. Thereafter, the bar is divided into devices in the cavity direction along device division lines 195 in FIG. 13 (at positions where a width on a B1 side of the device division line 195 is about 115 μm and a width on a B2 side of the device division line 195 is about 125 μm) thereby forming a plurality of chips of the two-wavelength laser device 60 bonded to the support substrate 101.

Thereafter, the blue-violet semiconductor laser device 50 is bonded to the two-wavelength laser device 60 and the support substrate 101 through the conductive adhesive layers 96 while the p-side pad electrodes 58 and the pad electrode 91 are opposed to the pad electrode 94 and the n-side pad electrode 63, respectively, as shown in FIG. 7. The melting point of the conductive adhesive layers 95 is higher than the melting point of the conductive adhesive layers 96, and hence the conductive adhesive layers 95 are not melted when bonding the blue-violet semiconductor laser device 50 to the support substrate 101. Therefore, there is no such a problem that the two-wavelength laser device 60 is detached from the support substrate 101 or that a bonding position of the two-wavelength laser device 60 is displaced in this step. Then, the lower surface of the support substrate 101 is fixed onto an upper surface of the electrode layer 117 formed on a surface of the conductive base 115 through the conductive adhesive layer 97.

Finally, the base 115 is fixed onto the protruding block 116 through the conductive adhesive layer not shown) while pressing the former against the latter with a collet (not shown) of ceramics. The semiconductor laser apparatus 100 (see FIG. 7) is formed in this manner.

As hereinabove described, a thickness of the two-wavelength laser device 60 is reduced by removing the GaAs substrate 65 by etching, and thereafter the n-side pad electrode 63 is so formed in the two-wavelength laser device 60 that the upper surface thereof overlaps with the lower surface of the planar portion 51a, whereby a distance (thickness) reaching the active layers 73 and 83 from the n-side electrode 59 through the n-type GaN substrate 51 and the n-type contact layer 61 is further reduced at a position where a part of the blue-violet semiconductor laser device 50 and the two-wavelength laser device 60 overlap with each other, and hence the electric resistance can be easily reduced. Consequently, an operating voltage of the two-wavelength laser device 60 is reduced, and hence heat generation can be suppressed in the semiconductor laser apparatus 100.

The planar portion 51a is bonded also on the upper surface of the n-side pad electrode 63, and hence the number of portions (4 portions in total) where the blue-violet semiconductor laser device 50 and the two-wavelength laser device 60 are bonded to the support substrate 101 is increased, whereby each of the laser devices can be reliably fixed, onto the support substrate 101. At this time, the n-side pad electrode 63 in the two-wavelength laser device 60 is electrically connected to the pad electrode 91 of the blue-violet semiconductor laser device 50 through the conductive adhesive layer 96, and hence cathode common connection in the semiconductor laser apparatus 100 can be easily achieved by bonding only the single metal wire 122 to the n-side electrode 59.

The metal wire 122 is bonded to the n-side electrode 59 of the blue-violet semiconductor laser device 50 having a thickness larger than the thickness of the two-wavelength laser device 60, whereby the thickness of the laser device is large, and hence the device can be inhibited from being easily damaged in wire bonding.

The two-wavelength laser device 60 is formed by monolithically forming the red semiconductor laser device 70 and the infrared semiconductor laser device 80 each made of a group III-V semiconductor including the greatest amount of phosphorus or arsenic as a group V element. In other words, the laser device layers (p-side pad electrodes 77 and 37) at an opposite side to the GaAs substrate 65, each serving as a bonded surface are bonded onto the region 101c of the support substrate 101 having higher thermal conductivity than the GaAs substrate 65 by a junction-down system after forming the red semiconductor laser device 70 and the infrared semiconductor laser device 80 by employing the GaAs substrate 65 having low thermal conductivity, and thereafter a step of removing the GaAs substrate 65 is applied. Thus, heat generated by the two-wavelength laser device 60 can be easily radiated to the base 115 through the support substrate 101.

The blue-violet semiconductor laser device 50 made of a group III-V semiconductor including the greatest amount of nitrogen as a group V element is applied to the “first semiconductor laser device” in the present invention, whereby the metal wire 122 can be easily wire-bonded to the blue-violet semiconductor laser device 50, and hence the yield can be improved even when the blue-violet semiconductor laser device 50 is formed employing the expensive n-type GaN substrate 51.

The thickness (about 100 μm) of the blue-violet semiconductor laser device 50 is rendered larger than the thickness (about 6 μm) of the two-wavelength laser device 60, whereby heat generated in the blue-violet semiconductor laser device 50 through the two-wavelength laser device 60 having a small thickness can be easily radiated to an external portion. In particular, the two-wavelength laser device 60 is made of a group III-V semiconductor, other than a nitride-based semiconductor, having low thermal conductivity as compared with a nitride-based semiconductor, and hence the aforementioned effect is significant.

When forming the two-wavelength laser device 60, the n-side ohmic electrode 62 and the n-side pad electrode 63 are formed on the n-type contact layer 61 after removing the GaAs substrate 65, whereby a distance (thickness) between the n-side pad electrode 63 and the active layers 73 and 83 can be reduced due to the removal of the GaAs substrate 65, and hence electric resistance between the n-side pad electrode 63 and the active layer 73 in the two-wavelength laser device 60 can be easily reduced. Consequently, the operating voltage of the two-wavelength laser device 60 is reduced, and hence heat generation can be suppressed in the semiconductor laser apparatus 100.

The ridge 56 is formed at the position deviating to the two-wavelength laser device 60 from the central portion of the projecting portion 51b in the blue-violet semiconductor laser device 50, and hence a laser beam-emitting point of the blue-violet semiconductor laser device 50 can be close to a laser beam-emitting point of the two-wavelength laser device 60 in a direction B1. Thus, a plurality of laser beams emitted from the semiconductor laser apparatus 100 can be rendered close to an optical axis of an optical system, whereby the semiconductor laser apparatus 100 and the optical system can be easily adjusted.

A height of the projecting portion 51b in the blue-violet semiconductor laser device 50 is rendered substantially equal to the thickness of the two-wavelength laser device 60, whereby a height from the lower surface of the support substrate 101 to the active layer 53 of the blue-violet semiconductor laser-device 50 and a height from the lower surface of the support substrate 101 to the active layers 73 and 83 of the two-wavelength laser device 60 can approximate each other, and hence the laser beam-emitting points can be aligned in the lateral direction.

A width (about 100 μm) of the blue-violet semiconductor laser device 50 is rendered smaller than the width of the support substrate, whereby the width of the blue-violet semiconductor laser device 50 can be narrowed, and hence the yield of the blue-violet semiconductor laser devices 50 per n-type GaN substrate 51 can be increased in the manufacturing process, and the manufacturing cost for the blue-violet semiconductor laser device 50 can be reduced. When the first semiconductor laser device of the present invention is a nitride-based semiconductor laser in particular, a nitride-based semiconductor substrate is expensive, and hence a cost-decreasing effect is significant.

The blue-violet semiconductor laser device 50 is so bonded to the support substrate 101 as to partly expose the upper surface of the n-side pad electrode 63 of the two-wavelength laser device 60, whereby the width of the blue-violet semiconductor laser device 50 can be narrowed, and hence the yield of the blue-violet semiconductor laser devices 50 per n-type GaN substrate 51 can be increased in the manufacturing process, and the manufacturing cost for the blue-violet semiconductor laser device 50 can be reduced similarly to the above.

In the blue-violet semiconductor laser device 50, the active layer 53 is arranged on a side (the C1 side) bonded to the support substrate 101, whereby the height from the lower surface of the support substrate 101 to the active layer 53 of the blue-violet semiconductor laser device 50 and the height from the lower surface of the support substrate 101 to the active layers 73 and 83 of the two-wavelength laser device 60 can approximate each other.

In the two-wavelength laser device 60, the ridges 75 and 85 of the laser devices are formed at the respective positions deviating to the blue-violet semiconductor laser device 50, and hence each of the two laser beam-emitting points that the two-wavelength laser device 60 has can be close to the laser beam-emitting point of the blue-violet semiconductor laser device 50 a direction B2.

The blue-violet semiconductor laser device 50 has the support portion 54a on an end of the projecting portion 51b on an opposite side (B2 side) of the blue-violet semiconductor laser device 50 to the two-wavelength laser device 60, whereby the support portion 54a can easily inhibit the blue-violet semiconductor laser device 50 from being inclined when bonding the blue-violet semiconductor laser device 50 to the pad electrode 94 of the support substrate 101.

The cavity length of the blue-violet semiconductor laser device 50 is rendered smaller than the cavity length of the two-wavelength laser device 60, whereby the cavity length of the blue-violet semiconductor laser device 50 can be short, and hence the yield of the blue-violet semiconductor laser devices 50 per n-type GaN substrate 51 can be increased in the manufacturing process, and the manufacturing cost for the blue-violet semiconductor laser device 50 can be reduced. In this case, higher output of the blue-violet semiconductor laser device 50 and the two-wavelength laser device 60 can be easily achieved.

The support substrate 101 has an insulating property. The wire-bonding portion 92a of the pad electrode 92 extending from the region 101c is formed on that rear of (on an A2 side of) the region 101d onto which the two-wavelength laser device 60 and the blue-violet semiconductor laser device 50 are not bonded. Thus, power can be easily supplied to the two-wavelength laser device 60 (red semiconductor laser device 70) by employing the pad electrode 92 extending from the region 101c arranged with the two-wavelength laser device 60 even when the support substrate 101 and the two-wavelength laser device 60 are electrically insulated from each other.

The melting point of the conductive adhesive layers 95 for bonding the two-wavelength laser device 60 is rendered higher than the melting point of the conductive adhesive layers 96 for bonding the blue-violet semiconductor laser device 50, whereby the conductive adhesive layers 95 are not melted when bonding the blue-violet semiconductor laser device 50 to the support substrate 101. Therefore, such a problem that the two-wavelength laser device 60 is detached from the support substrate 101 or that the bonding position of the two-wavelength laser device 60 is displaced in this step can be suppressed from occurring.

When forming the two-wavelength laser device 60, the heat treatment (a step of alloying under a temperature condition of about 500° C.) for alloying the n-side ohmic electrode 62 formed in the two-wavelength laser device 60 is performed before bonding the blue-violet semiconductor laser device 50 to the two-wavelength laser device 60 (n-side pad electrode 63), and thereafter the blue-violet semiconductor laser device 50 may be bonded to the heat-treated two-wavelength laser device 60. In other words, in a case where the two-wavelength laser device 60 is subjected to the aforementioned heat treatment after bonding the blue-violet semiconductor laser device 50 to the two-wavelength laser device 60 prior to the heat treatment, the treatment temperature (about 500° C.) in the heat treatment process has a pad influence on the p-side ohmic electrode layer 55 or the like formed in the blue-violet semiconductor laser device 50 so that the ohmic characteristics are disadvantageously easily deteriorated. On the other hand, in the aforementioned structure, the blue-violet semiconductor laser device 50 is bonded to the heat-treated two-wavelength laser device 60 so that the electrode layers (the p-side ohmic electrode layer 55 and the n-side electrode 59) of the blue-violet semiconductor laser device 50 is not influenced by the heat treatment (alloying). Thus, the characteristics of the ohmic electrode layer of the blue-violet semiconductor laser device 50 can be suppressed from being deteriorated.

When forming the two-wavelength laser device 60 by the n-type contact layer 61 made of a group III-V semiconductor including phosphorus or arsenic, the n-type contact layer 61 and the n-side ohmic electrode 62 are alloyed, whereby the ohmic characteristics between the n-type contact layer 61 and the n-side ohmic electrode 62 are improved and contact resistance therebetween can be further reduced.

The semiconductor device layer for constituting the laser device is formed after forming the etching stopper layer 66 on the upper surface of the GaAs substrate 65, whereby etching can be reliably stopped at the interface between the etching stopper layer 66 and the n-type contact layer 61 when removing the GaAs substrate 65 by the wet etching, and hence the thickness of the two-wavelength laser device 60 can be easily adjusted and the two-wavelength laser device 60 can be formed with a uniform thickness.

In the two-wavelength laser device 60 in a wafer state bonded to the support substrate 101, the n-type contact layer 61 in a region where a laser device structure is not formed is removed after removing the GaAs substrate 65 whereby the region 101d of the support substrate 101 can be easily exposed through the aforementioned step by forming the recess portion 68 above the pad electrode 94 on the support substrate 101. Thus, the blue-violet semiconductor laser device 50 can be easily bonded to the pad electrode 94 while fitting the blue-violet semiconductor laser device 50 in the recess portion 68 in a later step. When cleaving the two-wavelength laser device 60 in a wafer state in the form of a bar, a cleaved portion of the semiconductor device layer is reduced so that the cleavage can be easily performed, and the cavity facets with excellent flatness can be formed on the two-wavelength laser device 60. When dividing the two-wavelength laser device 60 in a wafer state, the device division can be easily performed at a portion of the support substrate 101 with a small thickness.

The wire-bonding portion 93a is exposed by forming the recess portion 68 above the wire-bonding portion 93a of the pad electrode 93 after bonding the two-wavelength laser device 60 to the support substrate 101 formed with the pad electrode 93, whereby the metal wire 124 can be easily wire-bonded to the wire-bonding portion 93a on the support substrate 101.

The blue-violet semiconductor laser device 50 previously brought into a chip state is bonded to the two-wavelength laser device 60 bonded to the support substrate 101, whereby the blue-violet semiconductor laser device 50 is separated into chips as shown in FIG. 9, and hence a large number of yields of the chips of the blue-violet semiconductor laser device 50 per wafer (n-type GaN substrate 51) can be secured.

The blue-violet semiconductor laser device 50 previously brought into a chip state is bonded to the two-wavelength laser device 60 brought into a chip state after bonded to the support substrate 101, whereby the device division can be easily performed at the portion of the support substrate 101 with a small thickness when dividing the two-wavelength laser device 60 in a wafer state.

### First Modification of First Embodiment

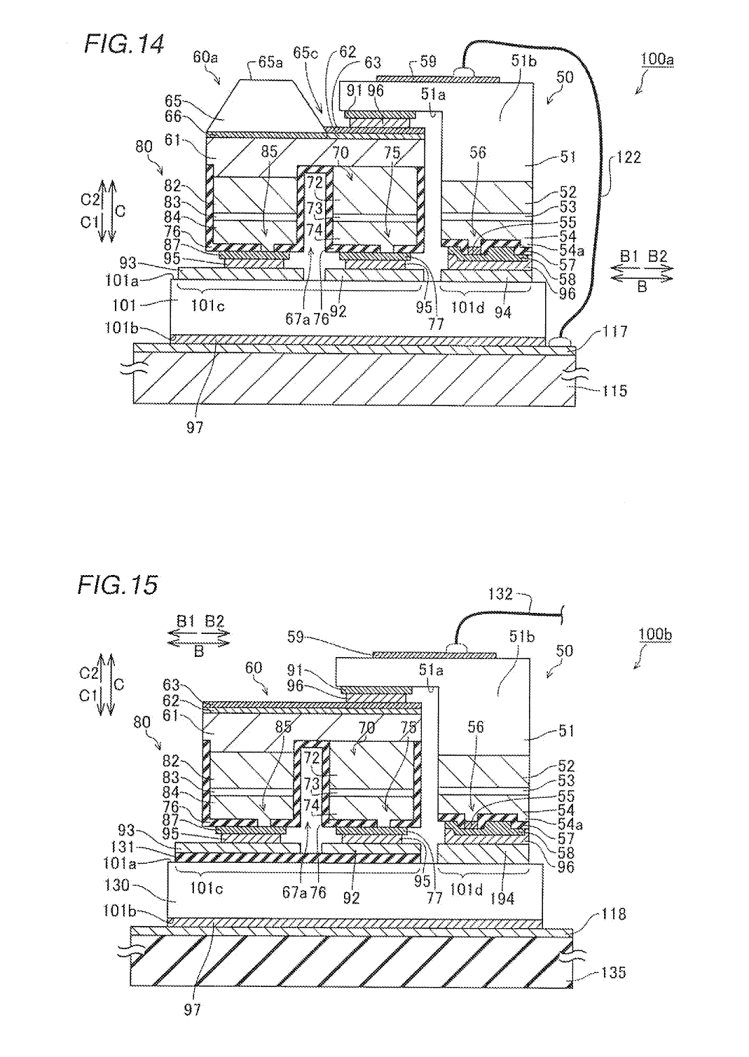

A first modification of the first embodiment is described with reference to FIG. 14. According to the first modification, a GaAs substrate 65 partly remains in a two-wavelength laser device 60a brought into a chip state, dissimilarly to the first embodiment. In the figure, a structure similar to that of the semiconductor laser apparatus 100 according to the first embodiment is denoted by the same reference numerals. The two-wavelength laser device 60a is an example of the “integrated laser device” in the present invention.

In a semiconductor laser apparatus 100a according to the first modification, as shown in FIG. 14, an n-side ohmic electrode 62 and an n-side pad electrode 63 for conducting with an n-type GaN substrate 51 of a blue-violet semiconductor laser device 50 are formed on an upper surface of an n-type contact layer 61 formed with a red semiconductor laser device 70 on the lower portion in the two-wavelength laser device 60a. The GaAs substrate 65 remains in a trapezoidal shape on the upper surface of the n-type contact layer 61 formed with an infrared semiconductor laser device 80 on the lower portion through an etching stopper layer 66. In other words, the GaAs substrate 65 remains, and hence a maximum thickness (in a direction C) of the two-wavelength laser device 60a not overlapping with the n-type GaN substrate 51 of the blue-violet semiconductor laser device 50 is increased.

The remaining structure of the semiconductor laser apparatus 100a is similar to that of the semiconductor laser apparatus 100 according to the first embodiment. In a manufacturing process of the semiconductor laser apparatus 100a according to the first modification of the first embodiment, when forming a recess portion 65c (see FIG. 14) on a surface 65a of the GaAs substrate 65, the GaAs substrate 65 in a region where the red semiconductor laser device 70 is formed on the lower portion is removed to form a wafer of the two-wavelength laser device 60a without removing the GaAs substrate 65 in a region where the red semiconductor laser device 70 is formed on the lower portion. The remaining manufacturing process of the semiconductor laser apparatus 100a is similar to that in the first embodiment.

As hereinabove described, the GaAs substrate 65 partly remains in the two-wavelength laser device 60a, and hence when bonding the blue-violet semiconductor laser device 50 to the support substrate 101 previously bonded with the two-wavelength laser device 60a, the two-wavelength laser device 60a can be rendered hard to break by pressing force resulting from bonding in the manufacturing process.

### Second Modification of First Embodiment

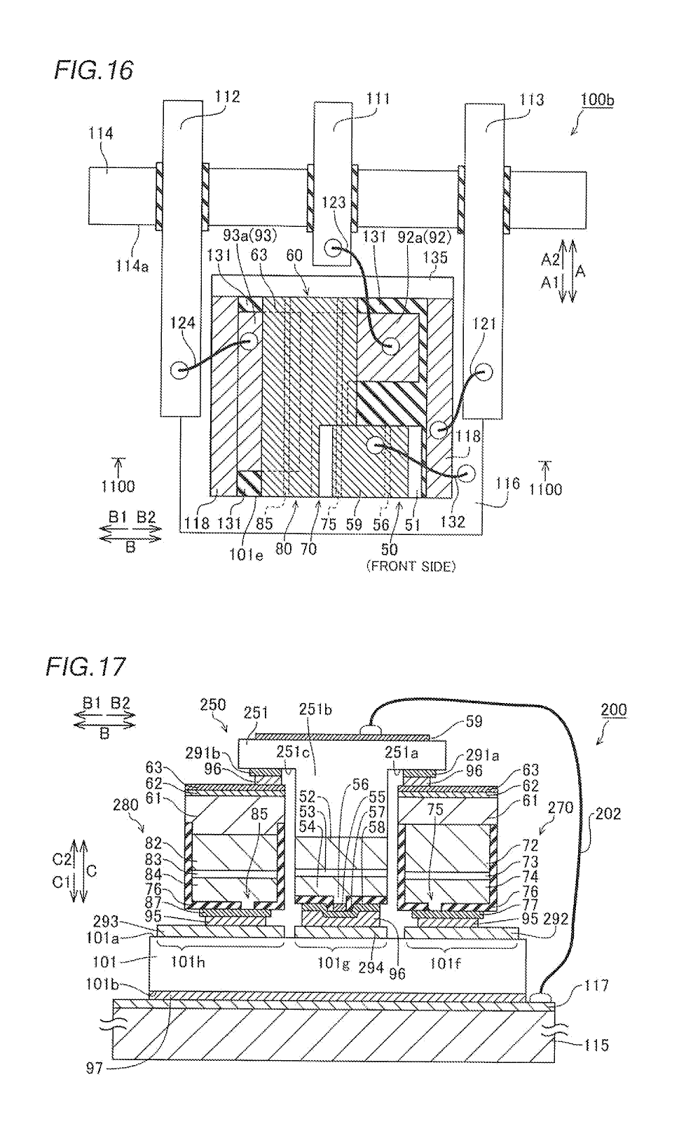

A second modification of the first embodiment is described with reference to FIGS. 15 and 16. According to the second modification, pad electrodes 92 and 93 for bonding a two-wavelength laser device 60 are formed on an n-type Si support substrate 130 having conductivity through an insulating film 131 made of SiO₂ dissimilarly to the first embodiment. FIG. 15 shows a section taken along the line 1100-1100 in FIG. 16. In the figures, a structure similar to that of the semiconductor laser apparatus 100 according to the first embodiment is denoted by the same reference numerals. The Si support substrate 130 is an example of the “support substrate” in the present invention.

In a semiconductor laser apparatus 100b according to the second modification, a blue-violet semiconductor laser device 50 and the two-wavelength laser device 60 are bonded onto a surface of the n-type Si support substrate 130 having conductivity to be adjacent to each other, as shown in FIG. 15. A pad electrode 194 conducting with the Si support substrate 130 is formed on the surface of the Si support substrate 130 in a region bonded with the blue-violet semiconductor laser device 50. The insulating film 131 made of SiO₂ for insulating the Si support substrate 130 from the pad electrodes 92 and 93 is formed on the surface or the Si support substrate 130 in a region bonded with the two-wavelength laser device 60. This insulating film 131 covers a region lateral (on a B2 side) to the two-wavelength laser device 60 and posterior (on an A2 side) to the blue-violet semiconductor laser device 50, as shown in FIG. 16. The electrode layer 118 is formed on a base 135.

Therefore, a p-side pad electrode 58 of the blue-violet semiconductor laser device 50 is electrically connected to a lead terminal 113 by a metal wire 121 wire-bonded to an electrode layer 118 through the pad electrode 194, the Si support substrate 130 and the electrode layer 118. At this time, the base 135 has an insulating property, and the electrode layer 118 and a protruding block 116 (see FIG. 16) do not conduct with each other. An n-side electrode 59 of the blue-violet semiconductor laser device 50 is directly connected to the protruding block 116 through a metal wire 132.

The remaining structure of the semiconductor laser apparatus 100b is similar to that of the semiconductor laser apparatus 100 according to the first embodiment. In a manufacturing process of the semiconductor laser apparatus 100b, the two-wavelength laser device 60 and the blue-violet semiconductor laser device 50 are bonded in this order to the Si support substrate 130 by employing the Si support substrate 130 formed with the pad electrodes 92 and 93 insulated from the Si support substrate 130 through the insulating film 131 and the pad electrode 194 directly conducting with the Si support substrate 130 on prescribed regions instead of the support Substrate 30 in the first embodiment. The remaining manufacturing process of the semiconductor laser apparatus 1001 is similar to that in the first embodiment.

### Second Embodiment

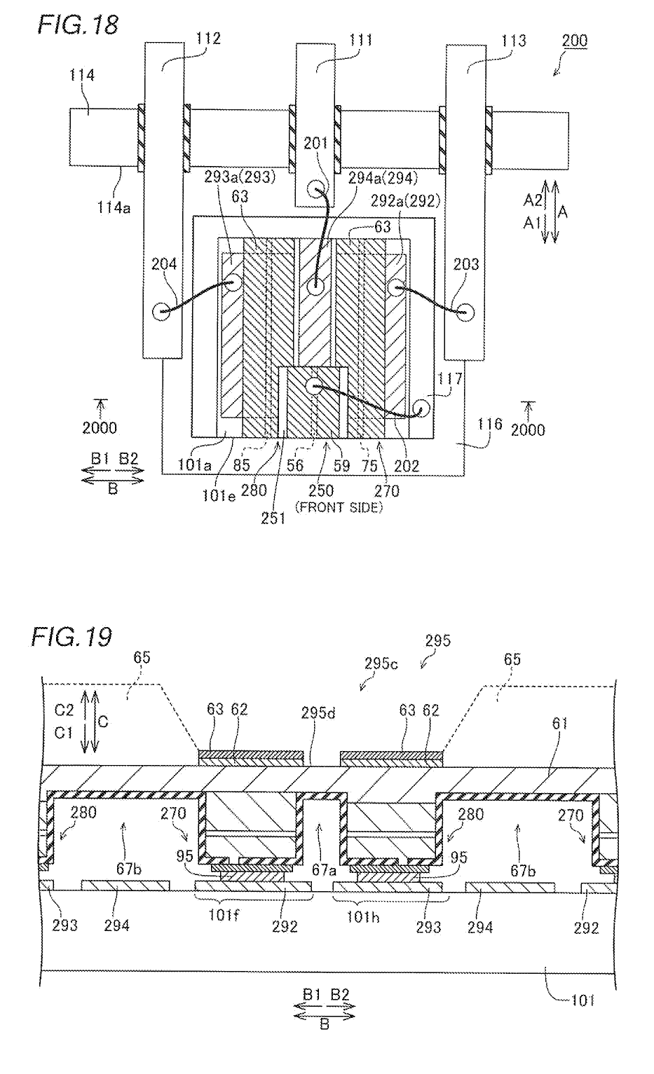

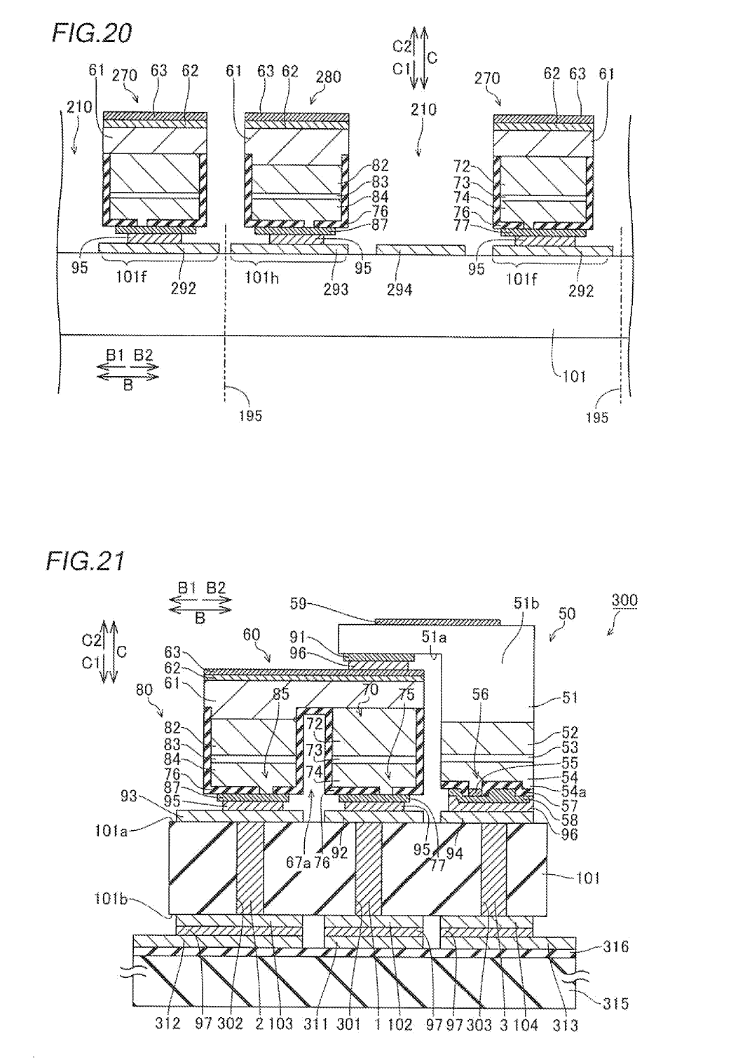

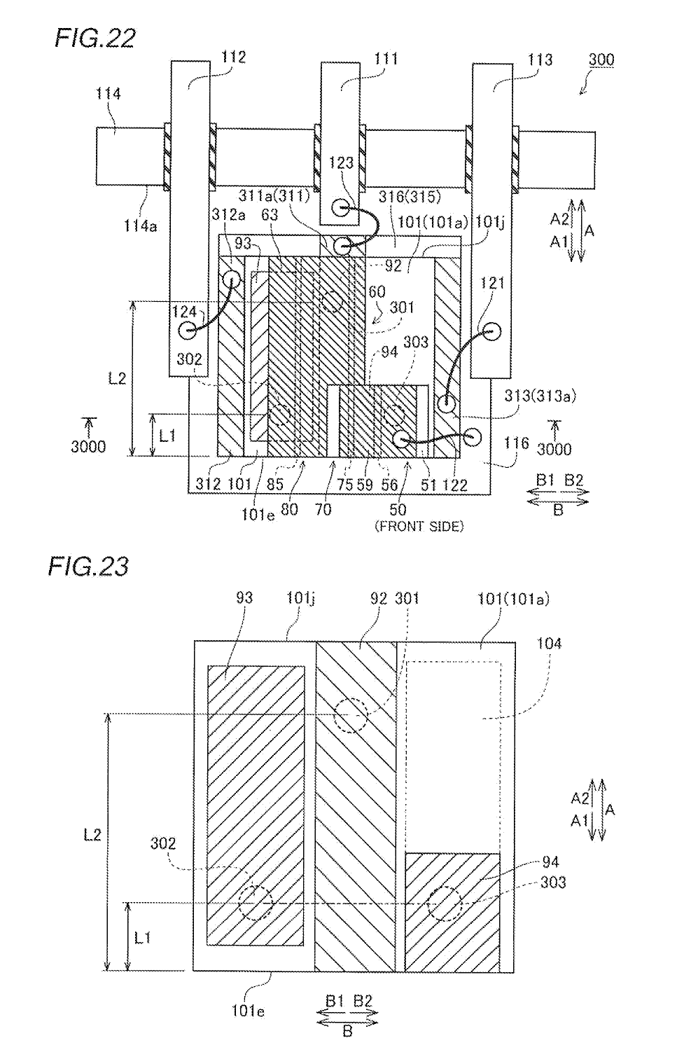

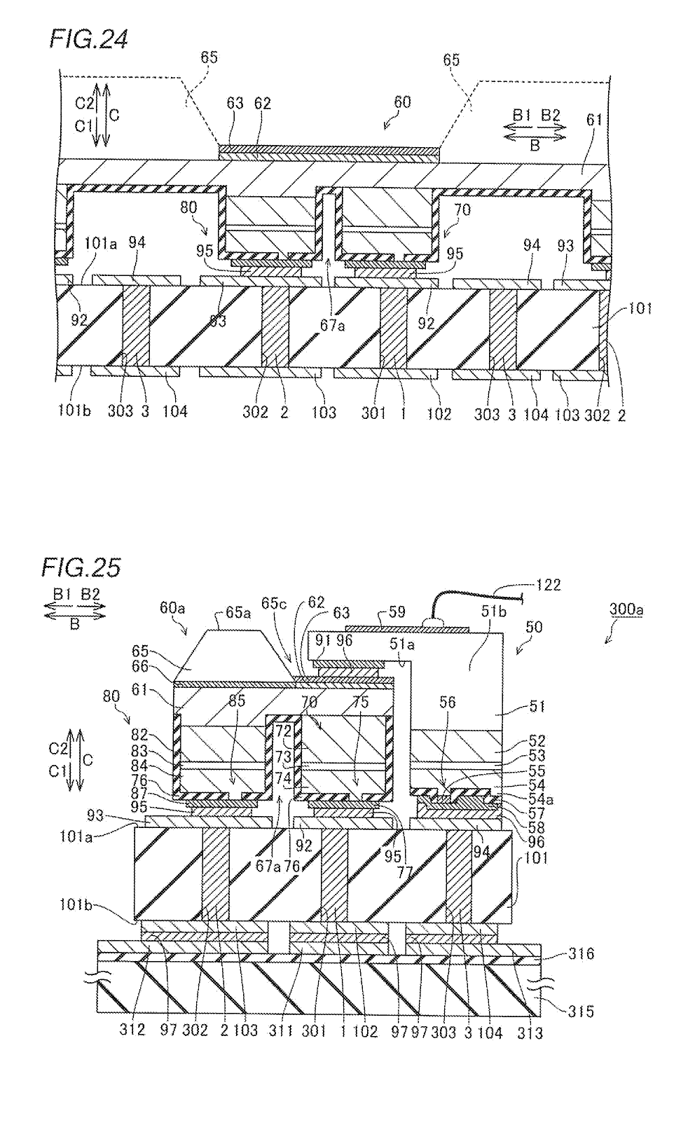

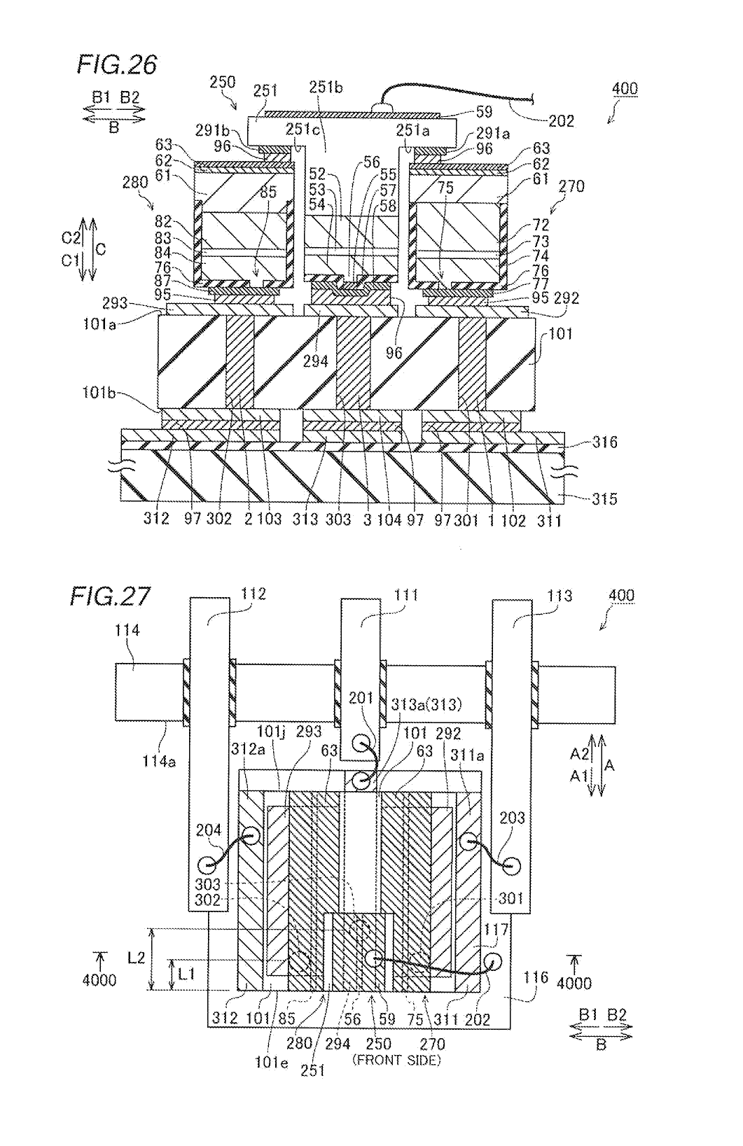

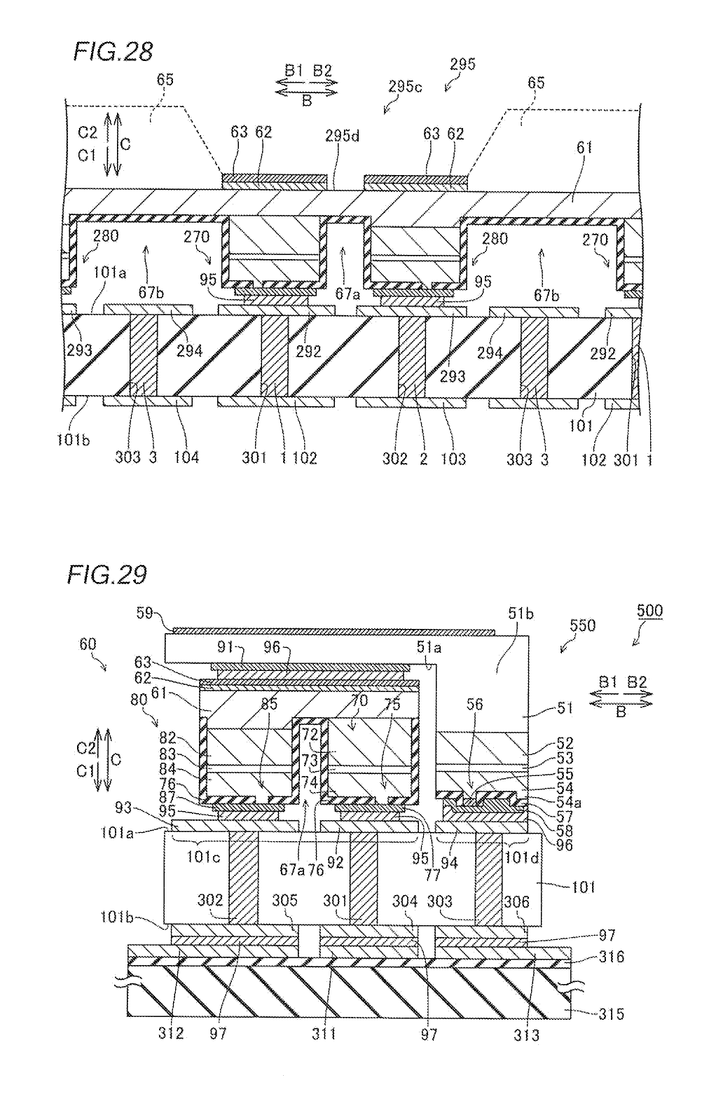

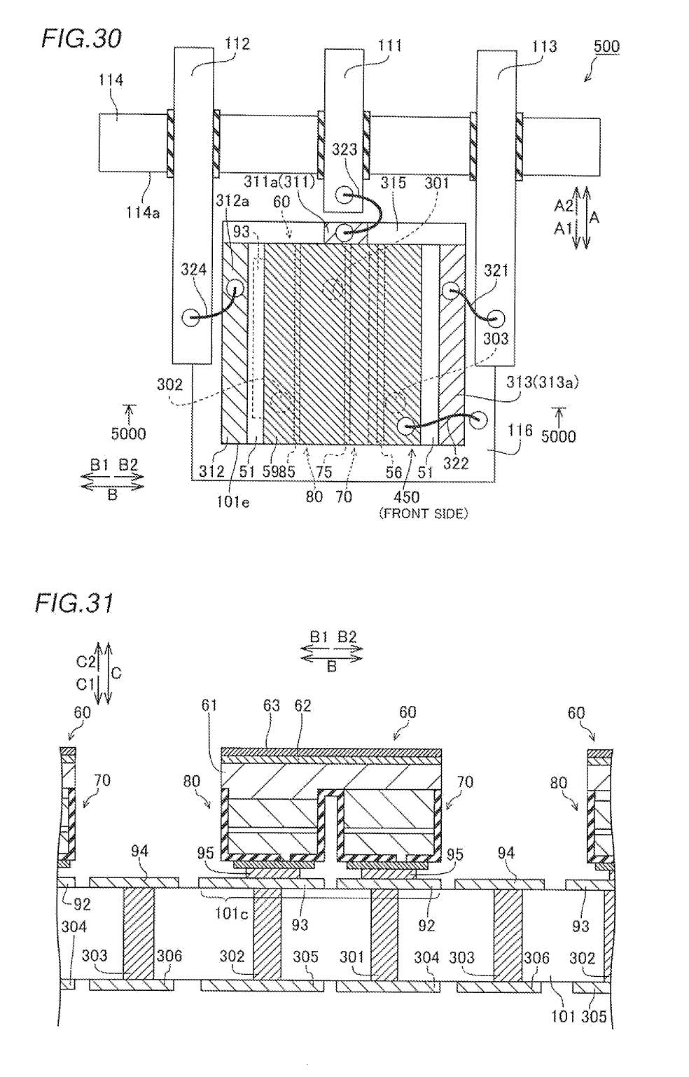

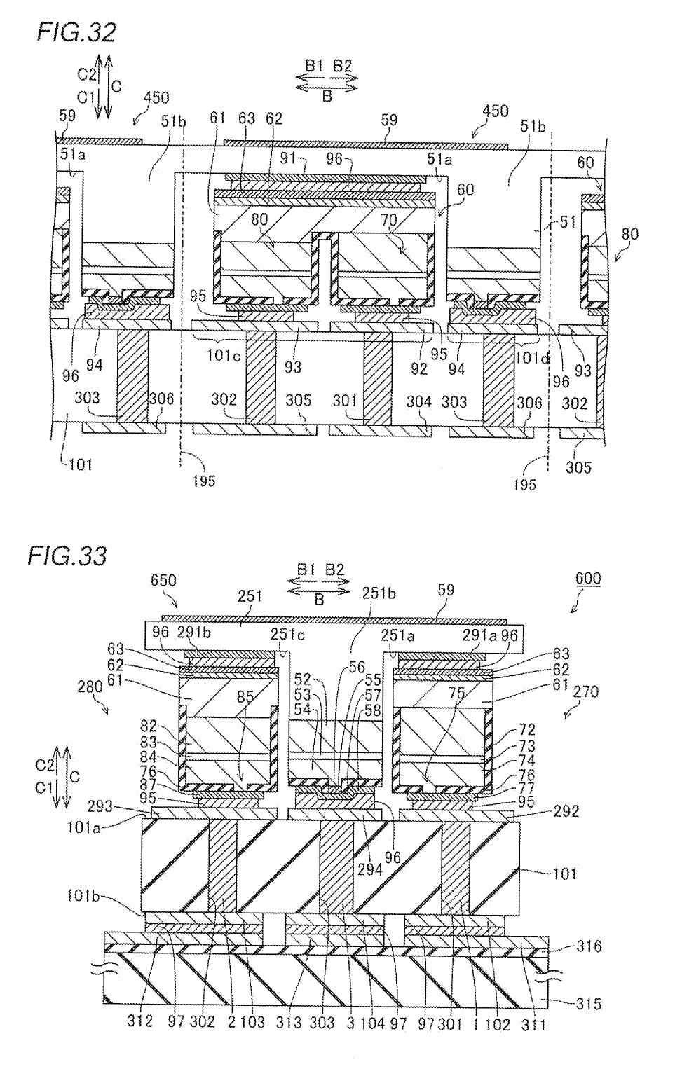

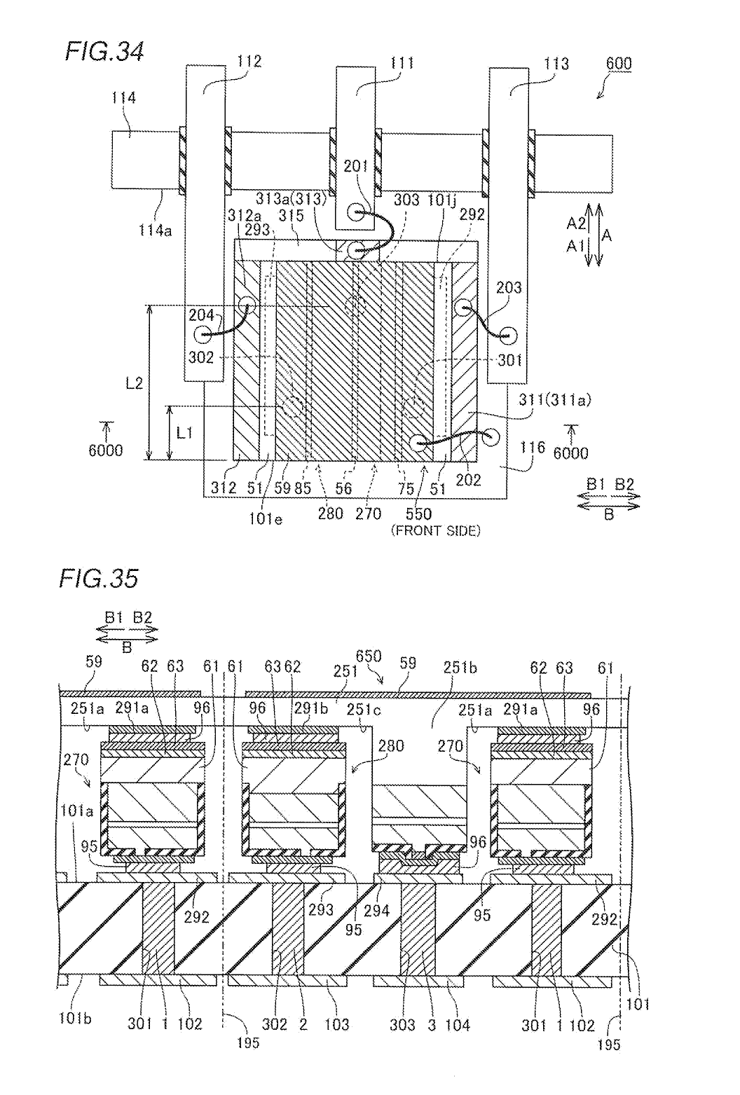

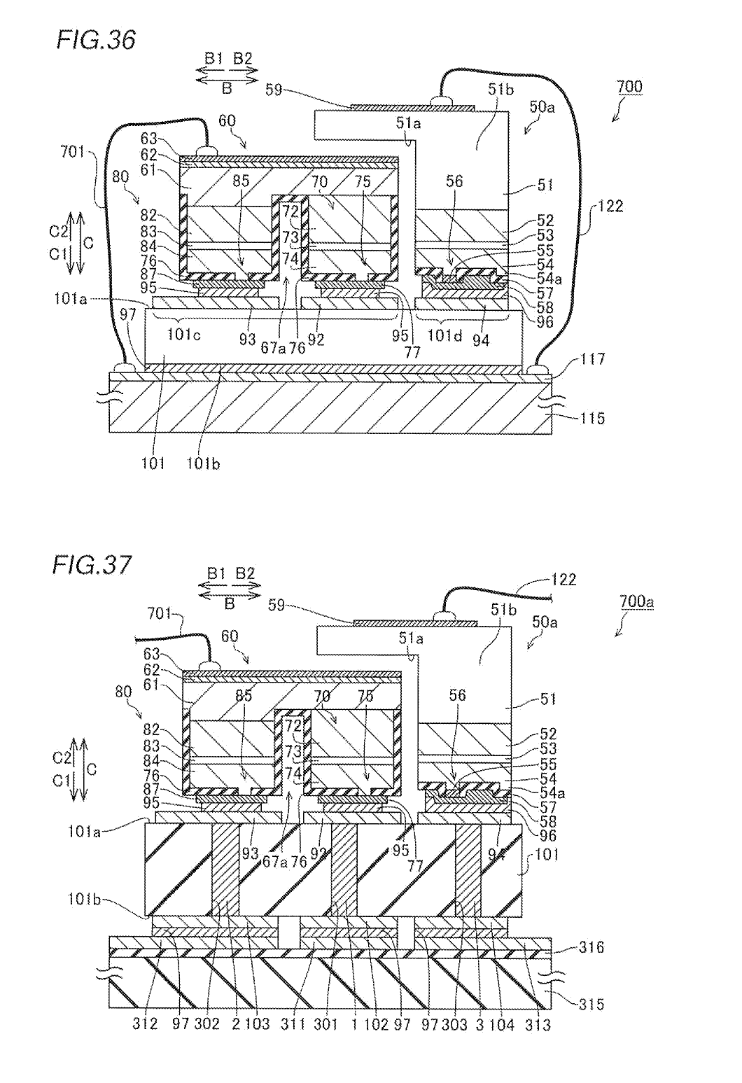

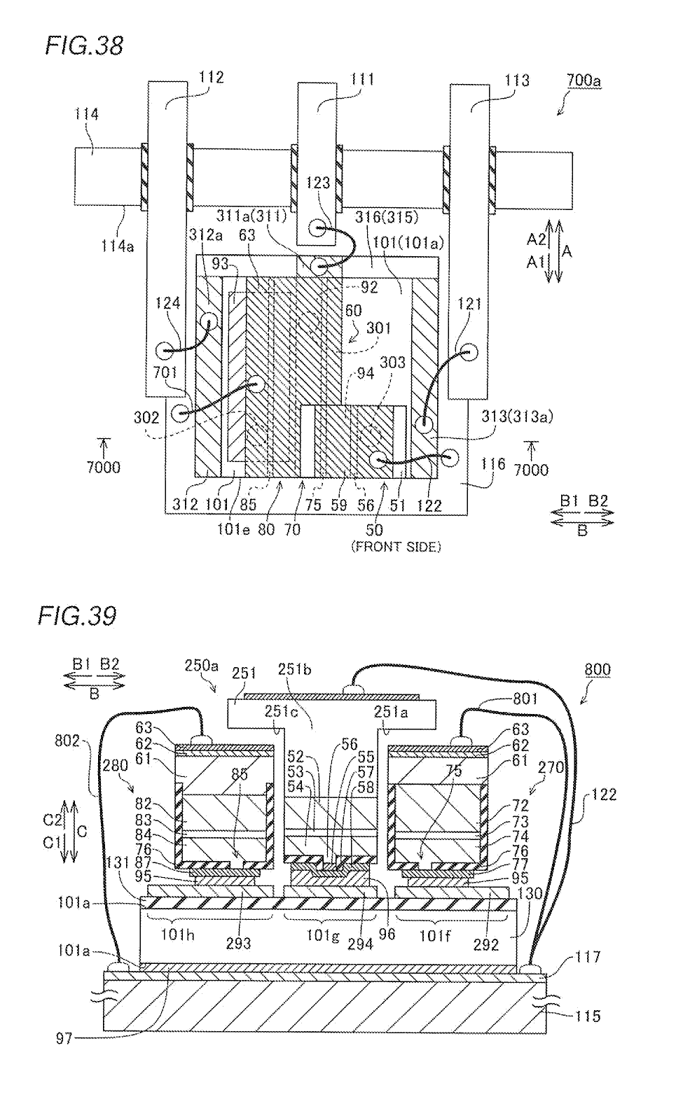

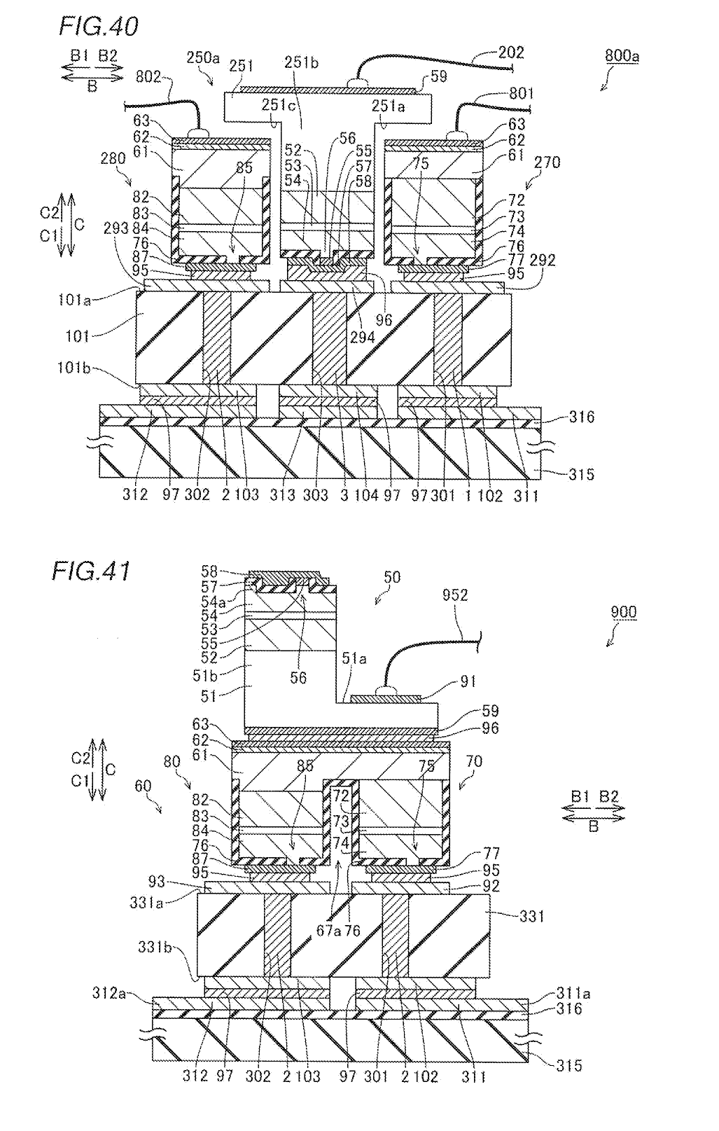

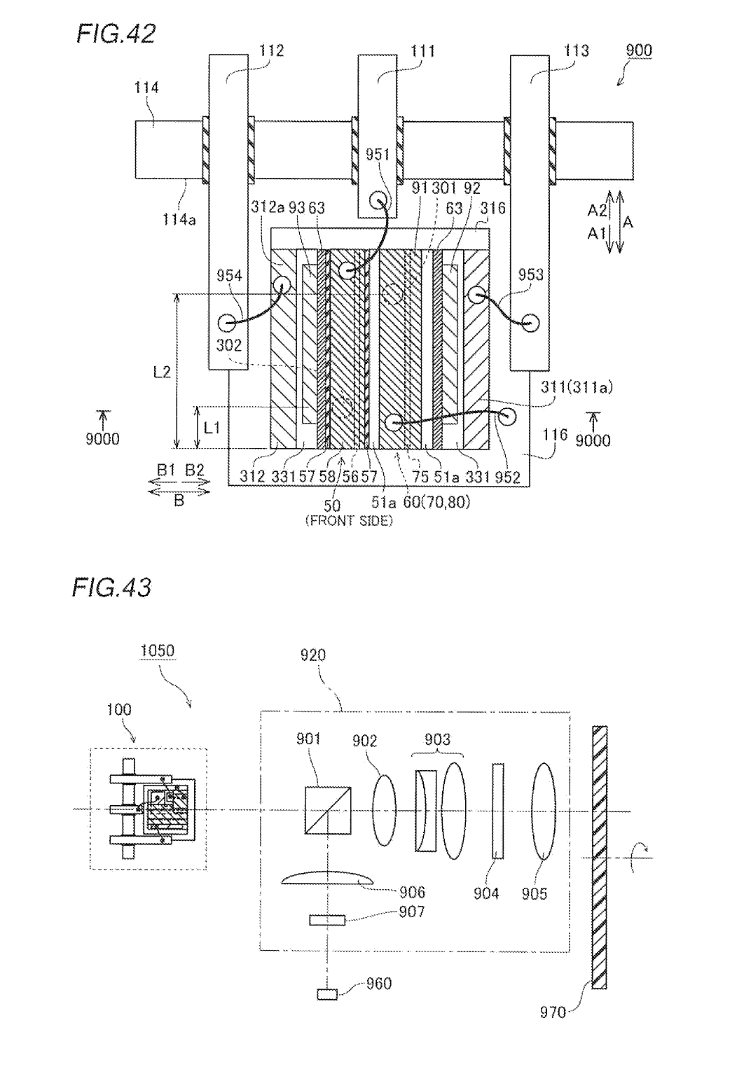

A second embodiment is described with reference to FIGS. 7, 17 and 18. In a semiconductor laser apparatus 200 according to the second embodiment, a blue-violet semiconductor laser device 250 having a cavity length of about 800 μm is arranged substantially in a center of the semiconductor laser apparatus 200 in a width direction (direction B), and a red semiconductor laser device 270 having a cavity length of about 1.5 mm and an infrared semiconductor laser device 280 having a cavity length of about 1.5 mm, separated from each other are arranged on both sides of the blue-violet semiconductor laser device 250, dissimilarly to the first embodiment. FIG. 17 shows a section taken along the line 2000-2000 in FIG. 18. In the figures, a structure similar to that of the semiconductor laser apparatus 100 according to the first embodiment is denoted by the same reference numerals.

In the semiconductor laser apparatus 200, the red semiconductor laser device 270, the blue-violet semiconductor laser device 250 and the infrared semiconductor laser device 280 are arranged on an upper surface 101a of a support substrate 101 in a lateral direction at intervals of about 5 μm, as shown in FIG. 17. The blue-violet semiconductor laser device 250 is an example of the “first semiconductor laser device” in the present invention. The red semiconductor laser device 270 and the infrared semiconductor laser device 280 are examples of the “second semiconductor laser device” in the present invention.

The blue-violet semiconductor laser device 250 has a projecting portion 251b formed by protruding a lower surface thereof on a substantially central region in a width direction of about 80 μm downwardly, having a width of about 20 μm and has planar portions 251a and 251c each having a width of about 30 μm on both sides of the projecting portion 251b. A laser device structure similar to that of the first embodiment is formed on the lower portion of the projecting portion 251b. A ridge 56 is formed on a substantially central portion of a semiconductor device layer, and the support portion 54a (see FIG. 7) shown in the first embodiment is not formed in a p-type cladding layer. The planar portions 251a and 251c are formed with pad electrodes 291a and 291b each extending along a cavity direction (direction A) of the blue-violet semiconductor laser device 250 in the form of a strip, respectively.

As shown in FIG. 18, pad electrodes 292, 293 and 294 each are formed through patterning on a surface of the substantially rectangular support substrate 101 to have a prescribed planar shape in plan view. More specifically, on the support substrate 101, the pad electrode 202 is arranged at a position opposed to a p-side pad electrode 77, and the pad electrode 293 is arranged at a position opposed to a p-side pad electrode 87. The pad electrode 294 is arranged in a region held between the pad electrodes 292 and 293 in a direction B, which is opposed to a p-side pad electrode 58. In FIG. 17, a region 101f (a region arranged with the pad electrode 292) of the support substrate 101, bonded with the red semiconductor laser device 270 is an example of the “first region” in the present invention, and a region 101h (a region arranged with the pad electrode 293) of the support substrate 101, bonded with the infrared semiconductor laser device 280 is an example of the “third region” in the present invention. A region 101g (a region arranged with the pad electrode 294) of the support substrate 101, bonded with the blue-violet semiconductor laser device 250 is an example of the “second region” in the present invention.

Therefore, the blue-violet semiconductor laser device 250 is bonded substantially on a center of the support substrate 101 in the width direction while the red semiconductor laser device 270 and the infrared semiconductor laser device 280 are bonded on a B2 side and a B1 side of both sides of the blue-violet semiconductor laser device 250, respectively, as shown in FIG. 17. The red semiconductor laser device 270 has a device width of about 40 μm, whose ridge 75 is formed at a position lying a distance of about 10 μm inward from a side surface of the red semiconductor laser device 270 closer to the blue-violet semiconductor laser device 250 (on the B1 side) toward the B2 side. The infrared semiconductor laser device 280 has a device width of about 40 μm, whose ridge 85 is formed at a position lying a distance of about 10 μm inward from a side surface of the infrared semiconductor laser device 280 closer to the blue-violet semiconductor laser device 250 (on the B2 side) toward the B1 side. Therefore, light-emitting portions of the right and left laser devices are arranged close to a light-emitting portion of the central laser device.

A lower surface of the p-side pad electrode 77 of the red semiconductor laser device 270 is bonded onto the pad electrode 292 of the support substrate 101. A lower surface of the p-side pad electrode 87 of the infrared semiconductor laser device 280 is bonded onto the pad electrode 293 of the support substrate 101. A lower surface of the p-side pad electrode 58 is so bonded onto the pad electrode 294 of the support substrate 101 that the planar portions 251a and 251c (lower surfaces of the pad electrodes 291a and 291b) of the blue-violet semiconductor laser device 250 overlap with upper surfaces (surfaces on a C2 side) of n-side pad electrodes 63 of the red semiconductor laser device 270 and the infrared semiconductor laser device 280, respectively. The lower surface (a surface on the C1 side) of the p-side pad electrode 77 of the red semiconductor laser device 270 and the lower surface (a surface on the C1 side) of the p-side pad electrode 27 of the infrared semiconductor laser device 280 are examples of the “third surface” in the present invention, and the upper surface (the surface on the C2 side) of the n-side pad electrode 63 of each laser device is an example of the “fourth surface” in the present invention. The planar portions 251a and 251c are examples of the “first section” and the “third section” in the present invention, respectively.

As shown in FIG. 18, the cavity length of the blue-violet semiconductor laser device 250 is shorter than the cavity lengths of the red semiconductor laser device 270 and the infrared semiconductor laser device 280. The three semiconductor laser devices (250, 270 and 280) are so bonded to the support substrate 101 that cavity facets thereof on a light-emitting side (an A1 side) are aligned on the same plane (facet 101e).

As shown in FIG. 18, the pad electrode 294 extends to an A2 side from between the blue-violet semiconductor laser device 250 and the support substrate 101 so as to be exposed from the blue-violet semiconductor laser device 250. The p-side pad electrode 58 of the blue-violet semiconductor laser device 250 is connected to a lead terminal 111 through a metal wire 201 wire-bonded to a wire-bonding portion 294a of the pad electrode 294. An n-side electrode 59 is connected to a protruding block 116 through a metal wire 202. The p-side pad electrode 77 of the red semiconductor laser device 270 is connected to a lead terminal 113 through a metal wire 203 wire-bonded to a wire-bonding portion 292a of the pad electrode 292 extending laterally (to the b2 side) while the p-side pad electrode 87 of the infrared semiconductor laser device 280 is connected to a lead terminal 112 through a metal wire 204 wire-bonded to a wire-bonding portion 293a of the pad electrode 293 extending laterally (to the B1 side). The n-side pad electrodes 63 of the red semiconductor laser device 270 and the infrared semiconductor laser device 280 are electrically connected to the pad electrodes 291a and 291b of the blue-violet semiconductor laser device 250 through conductive adhesive layers 96, respectively. Thus, the semiconductor laser apparatus 200 is formed in a state (cathode-common) where the p-side pad electrodes (53, 77 and 37) of the semiconductor laser devices are electrically connected to the respective lead terminals insulated from each other while the n-side electrodes (59 and 63) are electrically connected to a common cathode terminal.

Next, a manufacturing process of the semiconductor laser apparatus 200 is described with reference to FIGS. 17 to 20. FIGS. 19 and 20 show a state of a section taken along the line 2000-2000 in FIG. 1a in the manufacturing process.

A wafer of a two-wavelength laser device 295 formed through the manufacturing process similar to that of the first embodiment is bonded to the support substrate 101 shown in FIG. 19, and thereafter an n-side ohmic electrode 62 and the pad electrode 63 are formed by vacuum evaporation on a region of a bottom surface 295d not opposed to a recess portion 67e, where the bottom surface 295d is the bottom surface of a recess portion 295c. Thus, the n-side ohmic electrode 62 and the pad electrode 63 of each of the red semiconductor laser device 270 and the infrared semiconductor laser device 280 are formed. Then, an overall GaAs substrate 65 is removed, and an n-type contact layer 61 in a region (a region formed with recess portions 67a and 67b) not formed with the laser device structure is removed by scribing, wet etching or the like, as shown in FIG. 20. Thus, the red semiconductor laser device 270 and the infrared semiconductor laser device 280 are completely separated in the direction B.

Thereafter, the wafer is cleaved in the form of a bar to have a prescribed cavity length thereby forming the cavity facets of each semiconductor laser device. Then, the bar is divided into devices in the cavity direction along device division lines 195 in FIG. 20 thereby forming a plurality of chips of the support substrate 101 each having a recess portion 210 for bonding the blue-violet semiconductor laser device 250 in the central region and each arranged with the red semiconductor laser device 270 and the infrared semiconductor laser device 280 on the B2 and B1 sides of the recess portion 210, respective.

Thereafter, the blue-violet semiconductor laser device 250 brought into a chip state is bonded to the support substrate 101, as shown in FIG. 17. In other words, the blue-violet semiconductor laser device 250 is bonded to the support substrate 101 through conductive adhesive layers 96 while the p-side pad electrode 58 is opposed to the pad electrode 294 and the pad electrodes 291a and 291b are opposed to the respective n-side pad electrodes 63 of the red semiconductor laser device 270 and the infrared semiconductor laser device 280. At this time, the blue-violet semiconductor laser device 250 is so bonded to the support substrate 101 that the cavity facets thereof on the light-emitting side are aligned on the same plane as the cavity facets of the red semiconductor laser device 270 and the infrared semiconductor laser device 280 on the light-emitting side, as shown in FIG. 18.

The remaining manufacturing process of the semiconductor laser apparatus 200 is similar to that in the first embodiment.

As hereinabove described, the planar portions 251a and 251c are bonded onto the respective upper surfaces of the n-side pad electrodes 63 of the red semiconductor laser device 270 and the infrared semiconductor laser device 280, and hence the number of portions (5 portions in total) where the blue-violet semiconductor laser device 250 and the red and infrared semiconductor laser devices 270 and 280 are bonded to the support substrate 101 is increased, whereby each of the laser devices can be reliably fixed onto the support substrate 101. The remaining effects of the second embodiment are similar to those of the first embodiment.

### Third Embodiment

A third embodiment is described with reference to FIGS. 21 to 23. In a semiconductor laser apparatus 300 according to the third embodiment, three vias 301, 302 and 303 filled up with AuSn are formed in an insulating support substrate 101, dissimilarly to the first embodiment. FIG. 21 shows a section taken along the line 3000-3000 in FIG. 22. In the figures, a structure similar to that of the semiconductor laser apparatus 100 according to the first embodiment is denoted by the same reference numerals.

In the semiconductor laser apparatus 300, a blue-violet semiconductor laser device 50 and a two-wavelength laser device 60 are bonded onto a surface of the support substrate 101 to be adjacent to each other, as shown in FIG. 21, similarly to the first embodiment.

As shown in FIGS. 21 to 23, the vias 301, 302 and 303 penetrating through the support substrate 101 from an upper surface 101a to a lower surface 101b and each having an inner diameter of about 25 μm are formed on the support substrate 101 having a width of about 300 μm in a direction B and a length of about 1.5 mm in a direction A. The vias 302 and 303 are examples of the “first via” in the present invention, and the via 301 is an example of the “second via” in the present invention.

The via 301 is held between the vias 302 and 303 in the direction B, and the via 301 is formed at a position deviating to an opposite side (A2 side) to a light-emitting surface along a ridge 75 of a red semiconductor laser device 70 while the via 302 is formed at a position deviating to a light-emitting surface (A1 side) along a ridge 85 of an infrared semiconductor laser device 80. The via 303 is formed at substantially the same position as the via 302 along the direction A under the blue-violet semiconductor laser device 50. In other words, a distance L2 (about 1 mm) between a facet 101e of the support substrate 101 on a light-emitting surface side of the laser device and a center position of the via 301 along the direction A is longer than a distance L1 (about 400 μm) between the facet 101e and center positions of the vies 302 and 303 along the direction A. In FIG. 22, an outer shape of each of the vias is shown by a broken line. In FIG. 21, cross-sectional shapes of the vias 301 to 303 are all illustrated for convenience sake. The distances L1 and L2 are examples of the “first distance” and the “second distance” in the present invention, respectively. The facet 101e is an example of the “first facet” in the present invention.

Pad electrodes 92, 93 and 94 each having a substantially rectangular shape extending along the direction A in the form of a strip in plan view are formed through patterning on the upper surface 101a of the support substrate 101. The pad electrodes 92 and 93 extend over a substantially entire area from the facet 101e to a facet 101j on the A2 side. On the other hand, the pad electrode 94 is formed with substantially the same length as a cavity length of the blue-violet semiconductor laser device 50 from the facet 101e. The pad electrodes 92, 93 and 94 are formed at respective positions formed with the vies 301, 302 and 303. The pad electrodes 92, 93 and 94 are arranged in respective places on the support substrate 101 where a p-side pad electrode 77 of the red semiconductor laser device 70, a p-side pad electrode 87 of the infrared semiconductor laser device 80 and a p-side pad electrode 58 of the blue-violet semiconductor laser device 50 are bonded. Pad electrodes 102, 103 and 104 are formed at respective positions formed with the vias 301, 302 and 303 on the lower surface 101b of the support substrate 101. The pad electrodes 102 and 103 have the same respective shapes as the pad electrodes 92 and 93 and are formed at respective positions opposed to the pad electrodes 92 and 93. On the other hand, the pad electrode 104 extends over a substantially entire area from the facet 101e to the facet 101j. Therefore, the pad electrodes 92 and 102 are connected to a conductive member 1 of the via 301 to conduct with each other, the pad electrodes 93 and 103 are connected to a conductive member 2 of the via 302 to conduct with each other and the pad electrodes 94 and 104 are connected to a conductive member 3 of the via 303 to conduct with each other.

Extraction electrodes 311, 312 and 313 insulated from a base 315 through an insulating film 316 are formed on a surface of the base 315 of AlN or the like having an insulating property. As shown in FIG. 22, the extraction electrode 311 is formed at a position opposed to the pad electrode 102 and exposed to extend along a cavity direction of the red semiconductor laser device 70 from an end of the base 315 on the A1 side to an end of the base 315 on the A2 side in the form of a strip while the extraction electrode 311 is so exposed that a wire-bonding portion 311a provided on the end on the A2 side extends from between the base 315 (insulating film 316) and the support substrate 101 to the A2 side. The extraction electrode 312 is formed at a position opposed to the pad electrode 103 and exposed to extend along a cavity direction of the infrared semiconductor laser device 80 in the form of a strip while the extraction electrode 312 is so exposed that a wire-bonding portion 312a provided on an end of the base 315 on a B1 side extends from between the base 315 (insulating film 316) and the support substrate 101 to the B1 side. The extraction electrode 313 is formed at a position opposed to the pad electrode 103, arranged under the blue-violet semiconductor laser device 50 and so exposed that a wire-bonding portion 313a provided on an end of the base 315 on a B2 side extends from between the base 315 (insulating film 316) and the support substrate 101 to the B2 side. On the lower surface 101b of the support substrate 101, the pad electrodes 102, 103 and 104 are bonded to the extraction electrodes 311, 312 and 313 respectively through conductive adhesive layers 97 formed on whole surfaces of the pad electrodes. A total area of the pad electrodes 102, 103 and 104 is larger than a total area of the pad electrodes 92, 93 and 94 while the conductive adhesive layers 97 are formed on the substantially whole surfaces of the pad electrodes 102, 103 and 104. As a result, a bonding area of the pad electrode 102 and the extraction electrode 311, a bonding area of the pad electrode 103 and the extraction electrode 312 and a bonding area of the pad electrode 104 and the extraction electrode 313 are increased, and hence the base 315 and the support substrate 101 are strongly bonded to each other while heat is excellently radiated from the support substrate 101 to the base 315. The base 315 is an example of the “submount” in the present invention.

Thus, the p-side pad electrode 58 of the blue-violet semiconductor laser device 50 conducts with the extraction electrode 313 through the pad electrode 94, the via 303 (conductive member 3) and the pad electrode 104. In the red semiconductor laser device 70 of the two-wavelength laser device 60, the p-side pad electrode 77 conducts with the extraction electrode 311 through the pad electrode 92, the via 301 (conductive member 1) and the pad electrode 102. The p-side pad electrode 87 of the infrared) semiconductor laser device 80 conducts with the extraction electrode 312 through the pad electrode 93, the via 302 (conductive member 2) and the pad electrode 103.

As shown in FIG. 21, a lower surface of the p-side pad electrode 58 is so bonded onto the pad electrode 94 through the conductive adhesive layer 96 that a planar portion 51a overlaps with an upper surface of an n-side pad electrode 63 in a state where lower surfaces of the p-side pad electrodes 77 and 87 are bonded onto the pad electrodes 92 and 93 through conductive adhesive layers 95, respectively. At this time, the n-side pad electrode 63 and a pad electrode 91 are bonded to each other through a conductive adhesive layer 96.

As shown in FIG. 22, the p-side pad electrode 58 of the blue-violet semiconductor laser device 50 is connected to a lead terminal 113 through a metal wire 121 wire-bonded to the wire-bonding portion 313a extending to a 32 side of the extraction electrode 313 while an n-side electrode 59 is directly connected to a protruding block 116 through a metal wire 122. The wire-bonding portion 311a extends from between the support substrate 101 and the base 315 to an A2 side of the extraction electrode 311 to be exposed from the red semiconductor laser device 70. The p-side pad electrode 77 of the red semiconductor laser device 70 of the two-wavelength laser device 60 is connected to a lead terminal ill through a metal wire 123 wire-bonded to the wire-bonding portion 311a. The wire-bonding portion 312a extends from between the support substrate 101 and the base 315 to a B1 side of the extraction electrode 312 to be exposed from the infrared semiconductor laser device 80. The p-side pad electrode 87 of the infrared semiconductor laser device 80 is connected to a lead terminal 112 through a metal wire 124 wire-bonded to the wire-bonding portion 312a. As shown in FIG. 21, the n-side pad electrode 63 is electrically connected to the pad electrode 91 through the conductive adhesive layer 96. Thus, the semiconductor laser apparatus 300 is formed in a state (cathode-common) where the p-side pad electrodes (58, 77 and 37) are electrically connected to the lead terminals insulated from each other while the n-side electrodes (59 and 63) are electrically connected to a common cathode terminal.

The remaining structure of the semiconductor laser apparatus 300 is similar to that of the semiconductor laser apparatus 100 according to the first embodiment.

Next, a manufacturing process of the semiconductor laser apparatus 300 is described with reference to FIGS. 11 and 21 to 24. FIG. 24 shows a state of a section taken along the line 3000-3000 in FIG. 22 in the manufacturing process.

A wafer formed with the two-wavelength laser device 60 is prepared through the manufacturing process similar to that of the first embodiment, as shown in FIG. 11.

On the other hand, a plurality of the vias 301 to 303 penetrating from the upper surface 101a to the lower surface 101b are formed in a prescribed region of the support substrate 101, as shown in FIG. 24. At this time, the distance L2 between the first facet 101e (on the A1 side) of the support substrate 101 and the center position of the via 301 and the distance L1 between the facet 101e and the center position of each of the vias 302 and 303 are different from each other, as shown in FIG. 23. Thereafter, the vias 301 to 303 are filled up with the conductive members 1 to 3 (see FIG. 13), respectively, thereby forming planar surfaces having no unevenness on the upper surface 101a and the lower surface 101b. Thereafter, the pad electrodes 92 to 94 and the pad electrodes 102 to 104 are formed through patterning on the upper surface 101a and the lower surface 101b of the support substrate 101, respectively (see FIG. 23).

Then, the wafer formed with the two-wavelength laser device 60 is bonded to the support substrate 101 formed with the pad electrodes, as shown in FIG. 24. At this time, the wafer is bonded to the support substrate 101 through the conductive adhesive layers 95 while the p-side pad electrodes 77 and 87 are opposed to the pad electrodes 92 93, respectively. The remaining manufacturing process of the semiconductor laser apparatus 300 is substantially similar to that in the first embodiment.

As hereinabove described, the vias 301 to 303 are formed in the support substrate 101 while the extraction electrodes 311 to 313 are provided to correspond to the pad electrodes 102 to 104 formed on the lower surface of the support substrate 101, respectively, whereby the metal wires 121, 122 and 123 each can be wire-bonded away from positions where the semiconductor laser devices are bonded, and hence damage of the laser devices in the wire bonding can be suppressed.

The distance between the center position of one of the plurality of the vias and the facet of the support substrate 101 on the light-emitting surface side along the cavity direction is different from the distance between the center position of at least another one of the plurality of the vias and the facet of the support substrate 101 on the light-emitting surface side along the cavity direction, and hence the plurality of the vias can be efficiently provided in the support substrate 101 while increasing diameters of the individual vias even when the width of the support substrate 101 in the direction a is narrow.

The via 310 held between the vias 302 and 303 in the direction B is formed with deviation in the cavity direction, and hence the plurality of the vias can be more efficiently provided in the support substrate 101 while increasing the diameters of the individual vias even when the width of the support substrate 101 in the direction B is narrow.

The extraction electrode 311 held between the extraction electrodes 312 and 313 is formed along the cavity direction of the red semiconductor laser device 70 in the form of a strip while the wire-bonding portion 311a provided on the end on the A2 side opposite to the light-emitting surface side (A1 side) is exposed from between the base 315 and the support substrate 101, whereby the extraction electrodes 311 to 313 can be efficiently arranged on the base 315 and the metal wire 123 can be easily wire-bonded to the wire-bonding portion 311a exposed from between the base 315 and the support substrate 101 even when the width of the support substrate 101 is narrow. The remaining effects of the third embodiment are similar to those of the first embodiment.

### Modification of Third Embodiment

A modification of the third embodiment is described with reference to FIG. 25. According to this modification, a GaAs substrate 65 partly remains in a two-wavelength laser device 60a, dissimilarly to the third embodiment. In the figure, a structure similar to that of the semiconductor laser apparatus 300 according to the third embodiment is denoted by the same reference numerals. The two-wavelength laser device 60a is an example of the “second semiconductor laser device” in the present invention.

In a semiconductor laser apparatus 300a, as shown in FIG. 25, an n-side ohmic electrode 62 and an n-side pad electrode 63 for conducting with an n-type GaN substrate 51 of a blue-violet semiconductor laser device 50 are formed on an upper surface of an n-type contact layer 61 formed with an infrared semiconductor laser device 80 on the lower portion in the two-wavelength laser device 60a. The GaAs substrate 65 remains in a trapezoidal shape on the upper surface of the n-type contact layer 61 formed with a red semiconductor laser device 70 on the lower portion through an etching stopper layer 66. In other words, the GaAs substrate 65 remains, and hence a maximum thickness (in a direction C) of the two-wavelength laser device 60a is increased.

The remaining structure of the semiconductor laser apparatus 300a is similar to that of the semiconductor laser apparatus 300 according to the third embodiment. In a manufacturing process of the semiconductor laser apparatus 300a, when forming a recess portion 65c (see FIG. 25) on a surface 65a of the GaAs substrate 65, the GaAs substrate 65 in a region where the infrared semiconductor laser device 80 is formed on the lower portion is removed to form a wafer of the two-wavelength laser device 60a without removing the GaAs substrate 65 in a region where the red semiconductor laser device 70 is formed on the lower portion.

As hereinabove described, the GaAs substrate 65 partly remains in the two-wavelength laser device 60a, and hence the two-wavelength laser device 60a can be rendered hard to break by pressing force resulting from bonding when bonding the blue-violet semiconductor laser device 50 to the support substrate 101 previously bonded with the two-wavelength laser device 60a in the manufacturing process.

### Fourth Embodiment

A fourth embodiment is described with reference to FIGS. 7, 26 and 27. In a semiconductor laser apparatus 400 according to the fourth embodiment, a support substrate 101 formed with vias 301, 302 and 303 is employed, dissimilarly to the second embodiment. FIG. 26 shows a section taken along the line 4000-4000 in FIG. 27. In the figures, a structure similar to that of the semiconductor laser apparatus 200 according to the second embodiment is denoted by the same reference numerals.

In the semiconductor laser apparatus 400, a red semiconductor laser device 270, a blue-violet semiconductor laser device 250 and an infrared semiconductor laser device 280 are arranged on an upper surface 101a of the support substrate 101 formed with the vias 301, 302 and 303 in a lateral direction (direction B) at intervals of about 5 μm, as shown in FIG. 26.

As shown in FIGS. 26 and 27, the vias 301, 302 and 303 penetrating through the support substrate 101 from the upper surface 101a to a lower surface 101b are formed in the support substrate 101. Pad electrodes 292 and 102 are connected to a conductive member 1 of the via 301 to conduct with each other while pad electrodes 293 and 103 are connected to a conductive member 2 of the via 302 to conduct with each other. Further, pad electrodes 294 and 104 are connected to a conductive member 3 of the via 303 to conduct with each other. At this time, according to the fourth embodiment, as to a planar arrangement of the vias 301 to 303 formed in the support substrate 101, the via 301 for the red semiconductor laser device 270 and the via 302 for the infrared semiconductor laser device 280 each are formed at a position deviating to a facet 101e of the support substrate 101 on a light-emitting surface side while the via 303 for the blue-violet semiconductor laser device 250 is formed at a position deviating to an opposite side to a light-emitting surface, as shown in FIG. 27. In other words, a distance L2 (about 600 μm) between this facet 101e and a center position of the via 303 along a direction A is longer than a distance L1 (about 200 μm) between the facet 101e and center positions of the vias 301 and 302 along the direction A. The vias 301 and 302 are examples of the “first via” in the present invention, and the via 303 is an example of the “second via” in the present invention.

As shown in FIGS. 26 and 27, the pad electrodes 292, 293 and 294 each having a substantially rectangular shape extending along the direction A in the form of a strip in plan view are formed through patterning on the upper surface 101a of the support substrate 101. At this time, the pad electrodes 292 and 293 extend over a substantially entire area from the facet 101e to a facet 1013 on an A2 side. On the other hand, the pad electrode 294 is formed with substantially the same length as a cavity length of the blue-violet semiconductor laser device 250 from the facet 101e. The pad electrodes 292, 293 and 294 are formed at respective positions formed with the vias 301, 302 and 303. The pad electrodes 292, 293 and 294 are arranged in those respective places on the support substrate 101 where a p-side pad electrode 77 of the red semiconductor laser device 270, a p-side pad electrode 87 of the infrared semiconductor laser device 280 and a p-side pad electrode 58 of the blue-violet semiconductor laser device 250 are supposed to be bonded. At this time, the pad electrode 294 is held between the pad electrodes 292 and 293 in the direction B. The pad electrodes 102, 103 and 104 are formed at respective positions formed with the vias 301, 302 and 303 on the lower surface 101b of the support substrate 101. The pad electrodes 102 and 103 have the same respective shapes as the pad electrodes 292 and 293 and are formed at respective positions opposed to the pad electrodes 292 and 293. On the other hand, the pad electrode 104 extends over a substantially entire area from the facet 101e to the facet 101j. Therefore, the pad electrodes 292 and 102 are connected to the conductive member 1 of the via 301 to conduct with each other, the pad electrodes 293 and 103 are connected to the conductive member 2 of the via 302 to conduct with each other and the pad electrodes 294 and 104 are connected to the conductive member 3 of the via 303 to conduct with each other.

As shown in FIG. 27, extraction electrodes 311 to 313 are formed on a base 315 through an insulating film 316. According to the second embodiment, the extraction electrode 313 arranged under the blue-violet semiconductor laser device 250 extends along the direction A from an end on an A1 side to an end on the A2 side in the form of a strip, and a wire-bonding portion 313a provided on an opposite side to the light-emitting surface is exposed from between the base 315 and the support substrate 101. The extraction electrodes 311 and 312 extend laterally (to a B2 side and a B1 side) to the support substrate 101, and wire-bonding portions 311a and 312a are exposed from between the base 315 and the support substrate 101.

Therefore, the p-side pad electrode 58 of the blue-violet semiconductor laser device 250 is connected to a lead terminal 111 through a metal wire 201 wire-bonded to the wire-bonding portion 313a while an n-side electrode 59 is connected to a protruding block 116 through a metal wire 202. The p-side pad electrode 77 of the red semiconductor laser device 270 is connected to a lead terminal 113 through a metal wire 203 wire-bonded to the wire-bonding portion 311a while the p-side pad electrode 87 of the infrared semiconductor laser device 280 is connected to a lead terminal 112 through a metal wire 204 wire-bonded to the wire-bonding portion 312a. As shown in FIG. 26, n-side pad electrodes 63 of the red semiconductor laser device 270 and the infrared semiconductor laser device 280 are electrically connected to pad electrodes 291a and 291b of the blue-violet semiconductor laser device 250 through conductive adhesive layers 96, respectively. Thus, in the semiconductor laser apparatus 400, the p-side pad electrodes (58, 77 and 87) of the semiconductor laser devices are electrically connected to the respective lead terminals insulated from each other while the n-side electrodes (59 and 63) are electrically connected to a common cathode terminal. The remaining structure of the semiconductor laser apparatus 400 is similar to that of the semiconductor laser apparatus 200 according to the second embodiment.

A manufacturing process of the semiconductor laser apparatus 400 is now described with reference to FIGS. 13 and 26 to 28. FIG. 28 shows a state of a section taken along the line 4000-4000 in FIG. 27 in the manufacturing process.

As shown in FIG. 28, a wafer of a two-wavelength laser device 295 formed through the manufacturing process similar to that of the second embodiment is bonded onto the upper surface 101a of the support substrate 101 previously formed with the vias 301 to 303, the pad electrodes 292 to 294 and the pad electrodes 102 to 104, and thereafter an n-side ohmic electrode 62 and the pad electrode 63 are formed by vacuum evaporation on a region of a bottom surface 295d not opposed to a recess portion 67a, where the bottom surface 295d is the bottom surface of a recess portion 295c.

The remaining manufacturing process of the semiconductor laser apparatus 400 is similar to that in the second embodiment.

As hereinabove described, planar portions 251a and 251c are bonded onto respective upper surfaces of the n-side pad electrodes 63 of the red semiconductor laser device 270 and the infrared semiconductor laser device 280, and hence the number of portions (5 portions in total) where the blue-violet semiconductor laser device 250 and the red and infrared semiconductor laser devices 270 and 280 are bonded to the support substrate 101 is increased, whereby each of the laser devices can be reliably fixed onto the support substrate 101. The remaining effects of the fourth embodiment are similar to those of the second embodiment.

### Fifth Embodiment

A fifth embodiment is described with reference to FIGS. 29 to 32. In a semiconductor laser apparatus 500 according to the fifth embodiment, a blue-violet semiconductor laser device 550 in a wafer state is bonded to a support substrate 101 in a wafer state bonded with a two-wavelength laser device 60, thereafter the two wafers having been bonded to each other are cleaved simultaneously, and thereafter the semiconductor laser apparatus 500 is formed by simultaneously dividing the wafers into devices, dissimilarly to the manufacturing process of the third embodiment. FIGS. 29, 31 and 32 each show a section taken along the line 5000-5000 in FIG. 30. In the figures, a structure similar to that of the semiconductor laser apparatus 100 according to the third embodiment is denoted by the same reference numerals. The blue-violet semiconductor laser device 550 is an example of the “first semiconductor laser device” in the present invention.

As shown in FIG. 29, the semiconductor laser apparatus 500 is so bonded on a surface of the support substrate 101 formed with vias 301, 302 and 303 that the blue-violet semiconductor laser device 530 and the two-wavelength laser device 60 are adjacent to each other, similarly to the third embodiment.

Dissimilarly to the first embodiment, a planar portion 51a of an n-type GaN substrate 51 of the blue-violet semiconductor laser device 550 closer to the two-wavelength laser device 60, (on a B1 side) overlaps with a substantially entire region of an upper surface (upper surface of an n-side pad electrode 63) of the two-wavelength laser device 60, as shown in FIGS. 29 and 30. In other words, the blue-violet semiconductor laser device 550 is bonded onto the upper surface of the two-wavelength laser device 60 in a state of having a larger bonding area than the blue-violet semiconductor laser device 50 of the first embodiment. A cavity length of the blue-violet semiconductor laser device 550 and a cavity length of the two-wavelength laser device 60 are equal to each other and both about 1 mm, and the blue-violet semiconductor laser device 550 and the two-wavelength laser device 60 are so bonded to the support substrate 101 that cavity facets thereof on a light-reflecting side (an A2 side) are aligned on the same plane. In FIG. 30, an outer shape of the two-wavelength laser device 60 hidden under the n-type GaN substrate 51 is shown by a broken line. Pad electrodes 92, 93 and 94 extend over a substantially entire area from a facet 101e to a facet 101j on the A2 side. As shown in FIGS. 29 and 30, arrangements and shapes of the vias are similar to those of the third embodiment.

The via 301 is formed at a position deviating to an opposite side (A2 side) to a light-emitting surface along a ridge 75 of a red semiconductor laser device 70, the via 302 is formed at a position deviating to a light-emitting surface (A1 side) along a ridge 85 of an infrared semiconductor laser device 80 and the via 303 is formed at substantially the same position as the via 302 along a direction A under the blue-violet semiconductor laser device 50. In other words, a distance L2 (about 700 μm) between the facet 101e of the support substrate 101 and a center position of the via 301 along the direction A is longer than a distance L1 (about 300 μm) between the facet 101e and center positions of the vias 302 and 303 along the direction A. The remaining structure of the fifth embodiment is similar to that of the first embodiment.

In a manufacturing process of the semiconductor laser apparatus 500, as shown in FIG. 31, a wafer in which the two-wavelength laser device 60 is bonded on the surface of the support substrate 101 through conductive adhesive layers 95 is prepared, where the support substrate 101 is previously formed with the vias 301 to 303, the pad electrodes 92 to 94 and pad electrodes 304 to 306. As shown in FIG. 32, the blue-violet semiconductor laser device 550 in a wafer state is so bonded to the support substrate 101 through conductive adhesive layers 96 that the pad electrode 94 and the n-side pad electrode 63 are bonded to a pad electrode 58 and a pad electrode 91, respectively, and thereafter the support substrate 101 in a wafer state and the blue-violet semiconductor laser device 550 in a wafer state are cleaved in the form of a bar to form cavity facets of each semiconductor laser device. Then, the bar is divided into devices in a cavity direction along device division lines 195, thereby forming a plurality of chips of the semiconductor laser apparatus 500 (see FIG. 29). The remaining manufacturing process of the semiconductor laser apparatus 500 is substantially similar to that in the first embodiment.

As hereinabove described, the wafer bonded with the two-wavelength laser device 60 and the wafer formed with the blue-violet semiconductor laser device 550 are bonded to each other, and thereafter the semiconductor laser apparatus 500 can be formed while positions of the cavity facets of each semiconductor laser device are easily rendered equal to each other by cleaving the wafers simultaneously to form the cavity facets of each semiconductor laser device. The remaining effects of the fifth embodiment are similar to those of the third embodiment.

### Sixth Embodiment

A sixth embodiment is described with reference to FIGS. 33 to 35. In a semiconductor laser apparatus 600 according to the sixth embodiment, a blue-violet semiconductor laser device 650 in a wafer state is bonded to a support substrate 101 in a wafer state to which a red semiconductor laser device 270 and an infrared semiconductor laser device 280 completely separated from each other on the basis of a two-wavelength laser device 295 in a wafer state are bonded, thereafter the two wafers having been bonded to each other are cleaved simultaneously, and thereafter the semiconductor laser apparatus 600 is formed by simultaneously dividing the wafers into devices, dissimilarly to the manufacturing process of the second embodiment. FIG. 33 shows a section taken along the line 6000-6000 in FIG. 34. In the figures, a structure similar to that of the semiconductor laser apparatus 200 according to the second embodiment is denoted by the same reference numerals. The blue-violet semiconductor laser device 650 is an example of the “first semiconductor laser device” in the present invention.

In the semiconductor laser apparatus 600, as shown in FIG. 33, the blue-violet semiconductor laser device 650 is bonded onto a surface of the support substrate 101 formed with vias 301 to 303 and the red semiconductor laser device 270 and the infrared semiconductor laser device 280 are bonded onto the surface of the support substrate 101 on a B2 side and a B1 side of the blue-violet semiconductor laser device 650, respectively to have an arrangement of the blue-violet semiconductor laser device 650, the red semiconductor laser device 270 and the infrared semiconductor laser device 230 similar to that of the second embodiment.

Dissimilarly to the second embodiment, right and left planar portions 251a and 251c of an n-type GaN substrate 251 in the blue-violet semiconductor laser device 650 overlap with substantially entire regions of respective upper surfaces (upper surfaces of n-side pad electrodes 63) of the red semiconductor laser device 270 and the infrared semiconductor laser device 280, as shown in FIGS. 33 and 34. In other words, the blue-violet semiconductor laser device 650 is bonded onto the upper surface of each of the red semiconductor laser device 270 and the infrared semiconductor laser device 280 in a state of having a larger bonding area than the blue-violet semiconductor laser device 250 of the second embodiment. A cavity length of the blue-violet semiconductor laser device 650 and a cavity length of the red semiconductor laser device 270 (infrared semiconductor laser device 280) are equal to each other and both about 1 mm, and the blue-violet semiconductor laser device 653 and the red semiconductor laser device 270 (infrared semiconductor laser device 280) are so bonded to the support substrate 101 that cavity facets thereof on a light-reflecting side (an A2 side) are aligned on the same plane (facet 101e). Pad electrodes 292, 293 and 294 extend over a substantially entire area from the facet 101e to a facet 101j on the A2 side.

A via 301 is formed at a position deviating to an opposite side (A2 side) to a light-emitting surface along a ridge 75 of the red semiconductor laser device 270, a via 302 is formed at a position deviating to a light-emitting surface (A1 side) along a ridge 85 of the infrared semiconductor laser device 280 and a via 303 is formed at substantially the same position as the via 302 along a direction A under the blue-violet semiconductor laser device 650. In other words, a distance L2 (about 700 μm) between the facet 101e of the support substrate 101 and a center position of the via 301 along the direction A is longer than a distance L1 (about 300 μm) between the facet 101e and center positions of the vias 302 and 303 along the direction A. The remaining structure of the sixth embodiment is similar to that of the second embodiment.

In a manufacturing process of the semiconductor laser apparatus 600, a wafer in which the red semiconductor laser device 270 and the infrared semiconductor laser device 230 are bonded on the support substrate 101 formed through the manufacturing process similar to that of the second embodiment is prepared. As shown in FIG. 35, the blue-violet semiconductor laser device 650 in a wafer state is so bonded to the support substrate 101 through conductive adhesive layers 96 that a pad electrode 294, the n-side pad electrode 63 of the red semiconductor laser device 270 and the n-side pad electrode 63 of the infrared semiconductor laser device 280 are bonded to a pad electrode 58, a pad electrode 291a and a pad electrode 291b, respectively, and thereafter the support substrate 101 in a wafer state and the blue-violet semiconductor laser device 650 in a wafer state are cleaved in the form of a bar to form cavity facets of each semiconductor laser device. Then, the bar is divided into devices in a cavity direction along device division lines 195, thereby forming a plurality of chips of the semiconductor laser apparatus 600. The remaining manufacturing process of the semiconductor laser apparatus 600 is similar to that in the second embodiment. The effects of the sixth embodiment are similar to those of the second and fifth embodiments.

### Seventh Embodiment

A seventh embodiment is described with reference to FIGS. 7 and 36. In the figure, a structure similar to that of the semiconductor laser apparatus 100 according to the first embodiment is denoted by the same reference numerals. The blue-violet semiconductor laser device 50a an example of the “first semiconductor laser device” in the present invention.

In the semiconductor laser apparatus 700, as shown in FIG. 36, the n-type GaN substrate 51 and the two-wavelength laser device 60 are not bonded to each other although the n-type GaN substrate 51 is arranged to overlap with the two-wavelength laser device 60, and hence the n-type GaN substrate 51 and the n-side pad electrode 63 do not conduct with each other.

On the other hand, the n-side pad electrode 63 of the two-wavelength laser device 60 is connected to an electrode layer 117 on a base 115 through a metal wire 701. The remaining structure of the semiconductor laser apparatus 700 is similar to that of the semiconductor laser apparatus 100 according to the first embodiment. A manufacturing process of the semiconductor laser apparatus 700 is substantially similar to that of the semiconductor laser apparatus 100 according to the first embodiment except that the blue-violet semiconductor laser device 50a is bonded to a support substrate 101 without forming a pad electrode 91 on a planar portion 51a and without electrically connecting the n-type GaN substrate 51 and the n-side pad electrode 63 with each other.

### Modification of Seventh Embodiment

A modification of a seventh embodiment is described with reference to FIGS. 7, 37 and 38. In a semiconductor laser apparatus 700a according to the modification of the seventh embodiment, a blue-violet semiconductor laser device 50a and a two-wavelength laser device 60 are not bonded to each other such that an n-type GaN substrate 51 and an n-side pad electrode 63 are electrically connected with each other at a position where the blue-violet semiconductor laser device 50a and the two-wavelength laser device 60 overlap with each other, dissimilarly to the first embodiment. In the figures, a structure similar to that of the semiconductor laser apparatus 100 according to the first embodiment is denoted by the same reference numerals. FIG. 37 shows a section taken along the line 7000-7000 in FIG. 38. The blue-violet semiconductor laser device 50a is an example of the “first semiconductor laser device” in the present invention.

In the semiconductor laser apparatus 700a, as shown in FIG. 37, the n-type GaN substrate 51 and the two-wavelength laser device 60 are not bonded to each other although the n-type GaN substrate 51 is arranged to overlap with the two-wavelength laser device 60, and hence the n-type GaN substrate 51 and the n-side pad electrode 63 do not conduct with each other. Therefore, the n-side pad electrode 63 of the two-wavelength laser device 60 is directly connected to a protruding block 116 through a metal wire 701, as shown in FIG. 38.

The remaining structure of the semiconductor laser apparatus 700a is similar to that of the semiconductor laser apparatus 100 according to the first embodiment. A manufacturing process of the semiconductor laser apparatus 700a is substantially similar to that of the semiconductor laser apparatus 100 according to the first embodiment except that the blue-violet semiconductor laser device 50a is bonded to a support substrate 1C1 without forming a pad electrode 91 on a planar portion 51a and without electrically connecting the n-type GaN substrate 51 and the n-side pad electrode 63 with each other.

### Eighth Embodiment

An eighth embodiment is described with reference to FIGS. 17 and 39. In the figure, a structure similar to that of the semiconductor laser apparatus 200 according to the second embodiment is denoted by the same reference numerals. The blue-violet semiconductor laser device 250a is an example of the “first semiconductor laser device” in the present invention.

In the semiconductor laser apparatus 800, as shown in FIG. 39, each of the red and infrared semiconductor laser devices 270 and 280 and the n-type GaN substrate 251 are not bonded to each other although the n-type GaN substrate 251 is arranged to overlap with each of the red and infrared semiconductor laser devices 270 and 280, and hence the n-side pad electrode 63 of each of the red and infrared semiconductor laser devices 270 and 280 and the n-type GaN substrate 251 do not conduct with each other.

Pad electrodes 292 to 294 for bonding the respective three semiconductor laser devices are formed on an n-type Si support substrate 130 having conductivity through an insulating film 131 made of SiO₂.

The n-side pad electrode 63 of the red semiconductor laser device 270 is connected to an electrode layer 117 on a base 115 through a metal wire 801 while the n-side pad electrode 63 of the infrared semiconductor laser device 280 is connected to the electrode layer 117 through a metal wire 802. The remaining structure of the semiconductor laser apparatus 800 is similar to that of the semiconductor laser apparatus 200 according to the second embodiment (see FIG. 17). A manufacturing process of the semiconductor laser apparatus 800 is substantially similar to that of the semiconductor laser apparatus 200 according to the second embodiment except that the blue-violet semiconductor laser device 250a is bonded to the support substrate 130 without forming pad electrodes 291a and 291b on planar portions 251a and 251c and without electrically connecting the n-type GaN substrate 251 and each of the n-side pad electrodes 63 with each other.

### Modification of Eighth Embodiment

A modification of an eighth embodiment is described with reference to FIGS. 26 and 40. In the figure, a structure similar to that of the semiconductor laser apparatus 400 according to the fourth embodiment is denoted by the same reference numerals.

In the semiconductor laser apparatus 800a, as shown in FIG. 40, each of the red and infrared semiconductor laser devices 270 and 280 and the n-type GaN substrate 251 are not bonded to each other although the n-type GaN substrate 251 is arranged to overlap with each of the red and infrared semiconductor laser devices 270 and 280, and hence the n-side pad electrode 63 of each of the red and infrared semiconductor laser devices 270 and 280 and the n-type GaN substrate 251 do not conduct with each other.

The n-side pad electrode 63 of the red semiconductor laser device 270 is directly connected to a protruding block 116 through a metal wire 801 while the n-side pad electrode 63 of the infrared semiconductor laser device 280 is directly connected to the protruding block 116 through a metal wire 802. The remaining structure of the semiconductor laser apparatus 800a is similar to that of the semiconductor laser apparatus 400 according to the fourth embodiment (see FIG. 26). A manufacturing process of the semiconductor laser apparatus 800a is substantially similar to that of the semiconductor laser apparatus 400 according to the fourth embodiment except that the blue-violet semiconductor laser device 250a is bonded to a support substrate 101 without forming pad electrodes 291a and 291b on planar portions 251a and 251c and without electrically connecting the n-type GaN substrate 251 and each of the n-side pad electrodes 63 with each other.

### Ninth Embodiment

A ninth embodiment is described with reference to FIGS. 41 and 42. In a semiconductor laser apparatus 900 according to the ninth embodiment, only a two-wavelength laser device 60 is bonded onto an upper surface 331a of a support substrate 331 made of insulating Si while a blue-violet semiconductor laser device 50 is bonded onto an n-side pad electrode 63 of the two-wavelength laser device 60, dissimilarly to the first embodiment. FIG. 41 shows a section taken along the line 9000-9000 in FIG. 42. In the figures, a structure similar to that of the semiconductor laser apparatus 100 according to the first embodiment is denoted by the same reference numerals.

In the semiconductor laser apparatus 900, as shown in FIG. 41, the two-wavelength laser device 60 is bonded onto the upper surface 331a of the support substrate 331. The blue-violet semiconductor laser device 50 placed with an n-type GaN substrate 51 down (on a C1 side) is bonded onto the two-wavelength laser device 60 through a conductive adhesive layer 96. Thus, the support substrate 331 having a smaller width in a direction B than the support substrate 101 employed in the first embodiment is bonded onto a base 315, thereby forming the semiconductor laser apparatus 900.

As shown in FIG. 42, the blue-violet semiconductor laser device 50 is connected to a lead terminal 111 through a metal wire 951 wire-bonded to a p-side pad electrode 58 while a pad electrode 91 is directly connected to a protruding block 116 through a metal wire 952. A red semiconductor laser device 70 of the two-wavelength laser device 60 is connected to a lead terminal 113 through a metal wire 953 wire-bonded to a wire-bonding portion 311a extending to a B2 side of an extraction electrode 311 while an infrared semiconductor laser device 80 is connected to a lead terminal 112 through a metal wire 954 wire-bonded to a wire-bonding portion 312a extending to a B1 side of an extraction electrode 312. The n-side pad electrode 63 conducts with the n-type GaN substrate 51 through the conductive adhesive layer 96.

Only vias 301 and 302 for the two-wavelength laser device 60 are formed in the support substrate 331, only pad electrodes 92 and 93 are formed on the upper surface 331a and only pad electrodes 102 and 103 are formed on a lower surface 331b. In this case, one of either the via 301 or 302 is an example of the “first via” in the present invention, and the other is an example of the “second via” in the present invention. The remaining structure of the semiconductor laser apparatus 900 is substantially similar to that of the semiconductor laser apparatus 100 according to the first embodiment. A manufacturing process of the semiconductor laser apparatus 900 is substantially similar to that of the semiconductor laser apparatus 100 according to the first embodiment except that only the vias 301 and 302 for the two-wavelength laser device 60 are formed in the support substrate 331 and that the blue-violet semiconductor laser device 50 brought into a chip state is bonded onto the two-wavelength laser device 60 having been bonded to the support substrate 331 while a lower surface (n-side electrode 59) of the n-type GaN substrate 51 serves as a bonded surface. The remaining effects of the ninth embodiment are substantially similar to those of the first embodiment.

### Tenth Embodiment

An optical pickup 1050 comprising the semiconductor laser apparatus 100 according to a tenth embodiment of the present invention is described with reference to FIGS. 8 and 43.

In other words, as shown in FIG. 43, the optical pickup 1050 comprises the semiconductor laser apparatus 100 (see FIG. 3) according to the first embodiment, an optical system 920 having a polarizing beam splitter (polarizing BS) 901, a collimator lens 902, a beam expander 903, a λ/4 plate 904, an objective lens 905, a cylindrical lens 906 and an optical axis correction device 907 and a light detection portion 960.

In the optical system 920, the polarizing BS 901 totally transmits a laser beam emitted from the semiconductor laser apparatus 100, and totally reflects a laser beam returned from an optical disk 970. The collimator lens 902 converts the laser beam emitted from the semiconductor laser apparatus 100 and transmitted through the polarizing BS 901 to a parallel beam. The beam expander 903 includes a concave lens, a convex lens and an actuator (not shown). The actuator varies a distance between the concave lens and the convex lens in response to servo signals from a servo circuit (not shown). Thus, a wavefront state of the laser beam emitted from the semiconductor laser apparatus 100 is corrected.

The λ/4 plate 904 converts the linearly polarized laser beam, substantially converted to the parallel beam by the collimator lens 902, to a circularly polarized beam. Further, the λ/4 plate 901 converts the circularly polarized laser beam returned from the optical disk 970 to a linearly polarized beam. In this case, a direction of polarization of the linearly polarized beam is orthogonal to a direction of polarization of the linearly polarized laser beam emitted from the semiconductor laser apparatus 100. Thus, the polarizing BS 901 substantially totally reflects the laser beam returned from the optical disk 970. The objective lens 905 converges the laser beam transmitted through the λ/4 plate 904 on a surface (recording layer) of the optical disk 970. The objective lens 905 is movable in a focus direction, a tracking direction and a tilt direction by an objective lens actuator (not shown) in response to the servo signals (a tracking servo signal, a focus servo signal and a tilt servo signal) from the servo circuit.

The cylindrical lens 906, the optical axis correction device 907 and the light detection portion 960 are arranged to be along an optical axis of the laser beam totally reflected by the polarizing BS 901. The cylindrical lens 906 provides the incident laser beam with astigmatic action. The optical axis correction device 907 is formed by diffraction grating and so arranged that respective spots of zero-order diffracted light of blue-violet, red and infrared laser beams transmitted through the cylindrical lens 906 coincide with each other on a detection region of the light detection portion 960 described later.

The light detection portion 960 outputs a playback signal on the basis of an intensity distribution of the received laser beam. The light detection portion 960 has a detection region of a prescribed pattern, to obtain a focus error signal, a tracking error signal and a tilt error signal along with the playback signal. The actuator for the beam expander 903 and the objective lens actuator are feedback-controlled by the focus error signal, the tracking error signal and the tilt error signal. The optical pickup 1050 comprising the semiconductor laser apparatus 100 is constituted in the aforementioned manner.

As hereinabove described, the semiconductor laser apparatus 100 according to the first embodiment is employed in the optical pickup 1050, and hence the optical pickup 1050 comprising the semiconductor Laser apparatus 100 where sizes (thicknesses) of the laser devices is inhibited from increase and the metal wire can be easily wire-bonded to the laser device can be obtained.

The semiconductor laser apparatus 100 is employed in the optical pickup 1050 so that light emitted from each of the semiconductor laser devices can be incident at substantially the same angle with respect to (in a direction perpendicular to) a recording surface of the optical disk 970, and hence the optical pickup 1050 where optical spot quality of the semiconductor laser device in the optical disk 970 is inhibited from dispersion can be obtained.

Although the present invention has been described and illustrated in detail, it is clearly understood that the same is by way of illustration and example only and is not to be taken by way of limitation, the spirit and scope of the present invention being limited only by the terms of the appended claims.

For example, while the semiconductor laser apparatus employing the blue-violet semiconductor laser device as the first semiconductor laser device in the present invention and the red semiconductor laser device and the infrared semiconductor laser device as the second semiconductor laser device in the present invention is formed in each of the first to tenth embodiments, the present invention is not restricted to this. According to the present invention, an PGB three-wavelength semiconductor laser apparatus employed as a light source of a projector may be formed by employing a blue semiconductor laser device and a green semiconductor laser device as the first semiconductor laser device and a red semiconductor laser device as the second semiconductor laser device.

While the red semiconductor laser device and the infrared semiconductor laser device are bonded to the support substrate made of Si in each of the first to tenth embodiments, the present invention is not restricted to this. According to the present invention, a support substrate made of a material other than Si may be employed so far as the same has higher thermal conductivity than the GaAs substrate 65 serving as a growth substrate for crystal-growing the red semiconductor laser device and the infrared semiconductor laser device.

While nitride-based semiconductor layers are crystal-grown by MOCVD in the manufacturing process of each of the first to tenth embodiments, the present invention is not restricted to this. According to the present invention, the nitride-based semiconductor layers may be crystal-grown by halide vapor phase epitaxy, molecular beam epitaxy (MBE), gas-source MBE or the like.

While the blue-violet semiconductor laser device made of a group semiconductor including the greatest amount of nitrogen as a group V element is employed as the “first semiconductor laser device” in the present invention in each of the first to tenth embodiments, the present invention is not restricted to this. According to the present invention, the first semiconductor laser device may be made of a group III-V semiconductor including a lesser amount of phosphorus, arsenic or antimony than nitrogen in addition to nitrogen.

What is claimed is:

1. A semiconductor laser apparatus comprising:
a first semiconductor laser device including a first surface and a second surface opposite to said first surface;
an integrated laser device formed by a second semiconductor laser device and a third semiconductor laser device; and
a support substrate, wherein
said second semiconductor laser device includes a third surface and a fourth surface opposite to said third surface,
one surface of said support substrate has a first region and a second region other than said first region,
said first surface has a first section and a second section other than said first section,
said third surface is bonded onto said first region,
said first section overlaps with at least part of said fourth surface, and
said second section is bonded to said second region.

2. The semiconductor laser apparatus according to claim 1, wherein
said first semiconductor laser device further includes a step portion formed on said first surface,
a bottom portion of said step portion is said first section, and
a top portion of said step portion is said second section.

3. The semiconductor laser apparatus according to claim 2, wherein
a thickness of said integrated laser device is not more than a height from said bottom portion to said top portion.

4. The semiconductor laser apparatus according to claim 1, wherein
said first semiconductor laser device has a first waveguide extending in a first direction,
said first direction is in a plane of said support substrate,
a second direction is perpendicular to said first direction,
said second direction is in said plane,
said first waveguide is formed at a position opposed to said second region, and
said position deviates in said second direction to said integrated laser device from a center of said second section in said second direction.

5. The semiconductor laser apparatus according to claim 1, wherein
said first section is bonded onto said fourth surface.

6. The semiconductor laser apparatus according to claim 1, wherein
said first semiconductor laser device has a first active layer on a side closer to said first surface of said second section, and
said second semiconductor laser device and said third semiconductor laser device have a second active layer and a third active layer en a side closer to said third surface, respectively:

7. The semiconductor laser apparatus according to claim 1, wherein
said first semiconductor laser device has a first waveguide extending in a first direction,
said first direction is in a plane of said support substrate,
a second direction is perpendicular to said first direction,
said second direction is in said plane,
said second semiconductor laser device has a second waveguide extending in said first direction, and
said second waveguide is arranged at a position deviating in said second direction to said second section from a center of said second semiconductor laser device in said second direction.

8. A semiconductor laser apparatus comprising:
a first semiconductor laser device including a first surface and a second surface opposite to said first surface;
a second semiconductor laser device including a third surface and a fourth surface opposite to said third surface;
a third semiconductor laser device including a fifth surface and a sixth surface opposite to said fifth surface; and
a support substrate, wherein
one surface of said support substrate has a first region, a third region and a second region other than said first and said third regions,
said second region is held between said first region and said third region,
said first surface has a first section, a third section and a second section other than said first and said third sections,
said second section is held between said first section and said third section;
said third surface is bonded onto said first region,
said fifth surface is bonded onto said third region,
said first section and said third section overlap with said fourth surface and said sixth surface, respectively, and
said second section is bonded to said second region.

9. The semiconductor laser apparatus according to claim 1, wherein
said second semiconductor laser device and said third semiconductor laser device are made of a group III-V semiconductor including the greatest amount of phosphorus or arsenic as a group V element.

10. A semiconductor laser apparatus comprising:
a first semiconductor laser device including a first surface and a second surface opposite to said first surface;
a second semiconductor laser device including a third surface and a fourth surface opposite to said third surface; and
an insulating support substrate, wherein
said first semiconductor laser device is so arranged on said second semiconductor laser device that part of said first surface or said second surface overlaps with said fourth surface,
a first electrode is formed on said first surface,
a second electrode is formed on said third surface,
said support substrate includes an upper surface and a lower surface,
said second semiconductor laser device is bonded onto said upper surface,
said lower surface is an opposite surface to said upper surface,
said support substrate includes a via having a conductive member,
said via penetrates through said support substrate from said upper surface to said lower surface, and
at least either said first electrode or said second electrode is bonded onto said upper surface and connected to said conductive member.

11. The semiconductor laser apparatus according to claim 10, further comprising a submount, wherein
a top surface of said submount is bonded onto said lower surface,
an extraction electrode is formed on said top surface, and
said extraction electrode is connected to said conductive member.

12. The semiconductor laser apparatus according to claim 10, wherein
said via includes a first via and a second via,
said first via is connected to at least one of either said first semiconductor laser device or said second semiconductor laser device,
said second via is connected to at least the other of either said first semiconductor laser device or said second semiconductor laser device,
said first semiconductor laser device has a first waveguide extending in a first direction,
said first direction is in a plane of said support substrate,
said support substrate has a first facet in said first direction, and
a first distance between said first facet and a center position of said first via along said first direction and a second distance between said first facet and a center position of said second via along said first direction are different from each other.

13. The semiconductor laser apparatus according to claim 1, wherein
said first semiconductor laser device is made of a group III-V semiconductor including the greatest amount of nitrogen as a group V element.

14. The semiconductor laser apparatus according to claim 1, wherein
said support substrate has an insulating property or said one surface is covered with an insulating film,
said one surface has an area other than said first and said second regions,
said first semiconductor laser device and said integrated semiconductor laser device are not bonded onto said area, and
an extraction electrode extending from said first region or said second region is formed on said area.

15. The semiconductor laser apparatus according to claim 1, wherein
said first semiconductor laser device has a first waveguide extending in a first direction,
said first direction is in a plane of said support substrate,
a second direction is perpendicular to said first direction,
said second direction is in said plane, and
a width of said first semiconductor laser device in said second direction is smaller than a width of said integrated laser device in said second direction.

16. The semiconductor laser apparatus according to claim 1, wherein
said first semiconductor laser device has a first waveguide extending in a first direction, said first direction is in a plane of said support substrate, and
a length of said second semiconductor laser device in said first direction is larger than a length of said first semiconductor laser device in said first direction.

17. The semiconductor laser apparatus according to claim 1, wherein
said first semiconductor laser device has a first waveguide extending in a first direction,
said first direction is in a plane of said support substrate,
a second direction is perpendicular to said first direction,
said second direction is in said plane,
said first semiconductor laser device has a support portion on said second section, and
said support portion is arranged at a position further away from said integrated laser device than said first waveguide.

18. The semiconductor laser apparatus according to claim 5, wherein
said second surface is connected with a wire, and
said wire and said integrated laser device are electrically connected with each other.

19. The semiconductor laser apparatus according to claim 1, wherein
said first surface is bonded onto said support substrate through a second adhesive layer, and
said third surface is bonded onto said support substrate through a first adhesive layer.

20. The semiconductor laser apparatus according to claim 19, wherein
a melting point of said first adhesive layer is higher than a melting point of said second adhesive layer.
